(19) United States
(12) Patent Application Publication
(10) Pub. No.: US 2019/0013299 A1
(43) Pub. Date: Jan. 10, 2019

(54) SEMICONDUCTOR PACKAGES

(71) Applicant: Sang-won Lee, Seoul (KR)

(72) Inventor: Sang-won Lee, Seoul (KR)

(21) Appl. No.: 15/859,895

(22) Filed: Jan. 2, 2018

(30) Foreign Application Priority Data
Jul. 5, 2017 (KR) 10-2017-0085403

(51) Int. Cl. H01L 25/10; H01L 23/552; H01L 23/31; H01L 25/00; H01L 25/18; H01L 23/50

(52) U.S. Cl. CPC H01L 25/105; H01L 23/552; H01L 23/3135; H01L 25/50; H01L 2225/1058; H01L 23/3128; H01L 23/50; H01L 2225/1041; H01L 25/18

(57) ABSTRACT

Provided is a semiconductor package having high electric reliability. The semiconductor package includes a lower sub-semiconductor package including a lower semiconductor chip and a lower mold layer on the lower semiconductor chip and having a mold via hole, an upper sub-semiconductor package including an upper semiconductor chip, a filling layer that is between the lower sub-semiconductor package and the upper sub-semiconductor package, a connection via in the mold via hole that penetrates the lower mold layer and the filling layer and electrically connects the lower sub-semiconductor package to the upper sub-semiconductor package. The filling layer includes an extending part of the filling layer that extends into the mold via hole of the filling layer from a portion having a higher level than a top surface of the lower mold layer.

### CROSS-REFERENCE TO RELATED APPLICATION

This U.S. non-provisional patent application claims priority under 35 U.S.C. § 119 to Korean Patent Application No. 10-2017-0085403, filed on Jul. 5, 2017, in the Korean Intellectual Property Office, the disclosure of which is hereby incorporated in its entirety by reference.

### BACKGROUND

The inventive concept relates to a semiconductor package, and more particularly, to a semiconductor package having a package-on-package (PoP) structure or a panel level package (PLP) structure.

Due to the rapid development of electronic industries and demands of users, electronic devices have been further miniaturized and/or made light weight. Accordingly, a semiconductor device, i.e., a key component, of the electronic devices, may be highly integrated to accomplish a miniaturized and/or light weight device. Also, users may demand mobile products that are miniaturized and multi-functional.

In this regard, in order to provide a multi-function semiconductor package, a semiconductor package having a PoP structure or a PLP structure, in which a sub-semiconductor package is stacked on another sub-semiconductor package having a different function, is being developed. Also, the semiconductor package having the PoP structure or the PLP structure may include an electromagnetic wave shielding structure for tolerance to electromagnetic wave interference or to electromagnetic waves of each of the multi-function semiconductor packages.

### SUMMARY

The inventive concept provides a semiconductor package having high electric reliability.

According to some embodiments, there is provided a semiconductor package that includes a lower sub-semiconductor package with a lower semiconductor chip and a lower mold layer on the lower semiconductor chip and having a mold via hole, an upper sub-semiconductor package including an upper semiconductor chip, a filling layer filling between the lower sub-semiconductor package and the upper sub-semiconductor package, a connection via in the mold via hole that penetrates the lower mold layer and the filling layer and electrically connects the lower sub-semiconductor package to the upper sub-semiconductor package. The filling layer includes an extending part of the filling layer extending into the mold via hole from a portion of the filling layer having a higher level than a top surface of the lower mold layer.

According to some embodiments, there is provided a semiconductor package including a lower sub-semiconductor package including a lower package base substrate, a lower semiconductor chip attached on the lower package base substrate, and a lower mold layer on the lower semiconductor chip on a top surface of the lower package base substrate. The lower mold layer includes a mold via hole. The semiconductor package includes an upper sub-semiconductor package including an upper package base substrate and an upper semiconductor chip attached on the upper package base substrate, a filling layer that is between the lower sub-semiconductor package and the upper sub-semiconductor package, a connection via in the mold via hole that penetrates the lower mold layer and the filling layer, and electrically connects the lower package base substrate to the upper package base substrate, and an electromagnetic wave shielding member that covers a side surface of the lower sub-semiconductor package, a side surface of the filling layer, and/or side and/or top surfaces of the upper sub-semiconductor package. The connection via has a widest width at a level lower than a top surface of the lower mold layer.

According to some embodiments, there is provided a semiconductor package including a lower sub-semiconductor package including a lower semiconductor chip, a lower mold layer on the lower semiconductor chip, and a mold via hole. The semiconductor package includes an upper sub-semiconductor package including an upper semiconductor chip, and a filling layer that is between the lower sub-semiconductor package. The filling layer includes the upper sub-semiconductor package and includes an extending part and a protruding part. The extending part of the filling layer extends into the mold via hole from a portion having a higher level than a top surface of the lower mold layer. The protruding part of the filling layer protrudes farther than a side surface of the lower sub-semiconductor package and/or a side surface of the upper sub-semiconductor package in a same direction. The semiconductor package includes an electromagnetic wave shielding member including a metal material that covers the side surface of the lower sub-semiconductor package, a side surface of the filling layer, and/or side and/or top surfaces of the upper sub-semiconductor package. The semiconductor package includes a connection via in the mold via hole that penetrates the lower mold layer and the filling layer, and electrically connects the lower sub-semiconductor package to the upper sub-semiconductor package. The extending part of the filling layer includes a decreasing width as the extending part of the filling layer extends from a top surface of the lower mold layer into the mold via hole.

According to some embodiments, there is provided a semiconductor package including a first semiconductor package including a first semiconductor chip, an encapsulating layer on the first semiconductor chip, a insulating layer that is on the encapsulating layer, and a first connection via in a first via hole and a second connection via in a second via hole in the encapsulating layer. The first connection via and the second connection via extend through the encapsulating layer and the insulating layer. The insulating layer extends between the first connection via and the second connection via such that the insulating layer electrically isolates the first connection via from the second connection via.

It is noted that aspects of the inventive concept described with respect to one embodiment, may be incorporated in a different embodiment although not specifically described relative thereto. That is, all embodiments and/or features of any embodiment can be combined in any way and/or combination. These and other aspects of the inventive concepts are described in detail in the specification set forth below.

### BRIEF DESCRIPTION OF THE DRAWINGS

Embodiments of the inventive concept will be more clearly understood from the following detailed description taken in conjunction with the accompanying drawings in which:

FIGS. 1A and 1B are respectively a cross-sectional view and a partially enlarged cross-sectional view of a semiconductor package according to some embodiments;

FIGS. 2A through 2E are cross-sectional views for describing a method of manufacturing a semiconductor package, according to some embodiments;

FIG. 3A is a cross-sectional view for describing a method of manufacturing a semiconductor package, according to some embodiments;

FIGS. 3B and 3C are respectively a cross-sectional view and a partially enlarged cross-sectional view of a semiconductor package according to some embodiments;

FIG. 4A is a cross-sectional view for describing a method of manufacturing a semiconductor package, according to some embodiments;

FIGS. 4B and 4C are respectively a cross-sectional view and a partially enlarged cross-sectional view of a semiconductor package according to some embodiments;

FIG. 5A is a cross-sectional view for describing a method of manufacturing a semiconductor package, according to some embodiments;

FIGS. 5B and 5C are respectively a cross-sectional view and a partially enlarged cross-sectional view of a semiconductor package according to some embodiments;

FIG. 6A is a cross-sectional view for describing a method of manufacturing a semiconductor package, according to some embodiments;

FIGS. 6B and 6C are respectively a cross-sectional view and a partially enlarged cross-sectional view of a semiconductor package according to some embodiments;

FIGS. 7 through 11 are cross-sectional views of semiconductor packages according to some embodiments; and

FIG. 12 is a diagram of a configuration of a semiconductor package, according to some embodiments.

### DETAILED DESCRIPTION OF THE EMBODIMENTS

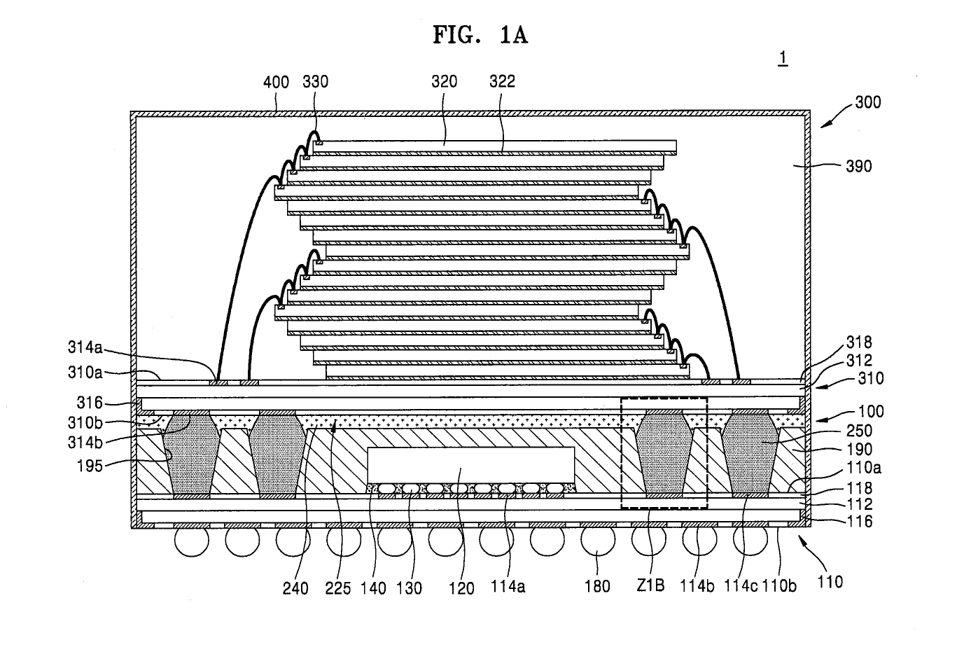

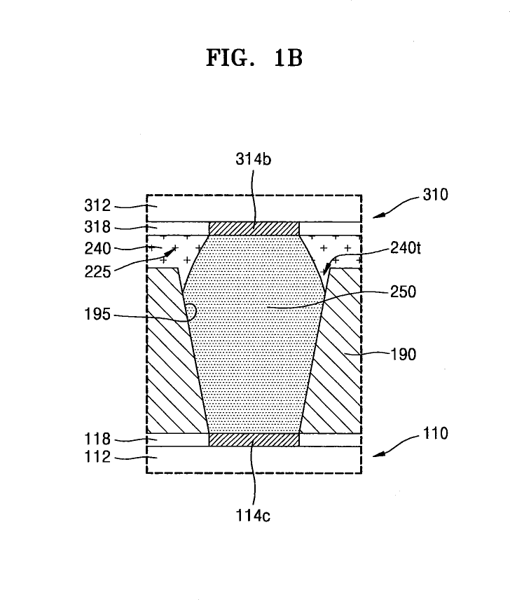

FIGS. 1A and 1B are respectively a cross-sectional view and a partially enlarged cross-sectional view of a semiconductor package 1 according to some embodiments. For example, FIG. 1B is an enlarged cross-sectional view of a region Z1b of FIG. 1A.

Referring to FIGS. 1A and 1B together, the semiconductor package 1 includes a lower sub-semiconductor package 100, an upper sub-semiconductor package 300 provided over the lower sub-semiconductor package 100, and an electromagnetic wave shielding member 400 covering at least some of surfaces of the lower and upper sub-semiconductor packages 100 and 300. According to some embodiments, the semiconductor package 1 may have a package-on-package (PoP) structure.

The lower sub-semiconductor package 100 may include a lower package base substrate 110 and a lower semiconductor chip provided over the lower package base substrate 110.

According to some embodiments, the lower package base substrate 110 may be a printed circuit board. For example, the lower package base substrate 110 may be a double-sided printed circuit board. The lower package base substrate 110 may include at least one lower base layer 112, and a plurality of lower connection pads provided on a top surface 110a and a bottom surface 110b of the lower package base substrate 110. A lower solder resist layer 118 may be provided on a top surface and a bottom surface of the lower base layer 112. The plurality of lower connection pads may not be covered by the lower solder resist layer 118, but may be exposed on the top and bottom surfaces 110a and 110b of the lower package base substrate 110. According to some embodiments, the lower solder resist layer 118 may be provided only on the bottom surface of the lower base layer 112, and may not be provided on the top surface thereof. According to some embodiments, the lower package base substrate 110 may include a plurality of the lower base layers 112 that are stacked on each other. For example, the lower package base substrate 110 may be a multi-layer printed circuit board.

According to some embodiments, the at least one lower base layer 112 may be formed of at least one material from among phenol resin, epoxy resin, and polyimide. For example, the at least one lower base layer 112 may include at least one material from among flame retardant 4 (FR4), tetrafunctional epoxy, polyphenylene ether, epoxy/polyphenylene oxide, bismaleimide triazine (BT), thermount, cyanate ester, polyimide, and liquid crystal polymer.

The plurality of lower connection pads may include a first lower connection pad 114a, a second lower connection pad 114b, and a third lower connection pad 114c. The first and third lower connection pads 114a and 114c may be provided on the top surface 110a of the lower package base substrate 110, and the second lower connection pad 114b may be provided on the bottom surface 110b of the lower package base substrate 110.

A lower connection terminal 130 attached to a lower semiconductor chip 120 may be attached to the first lower connection pad 114a. Accordingly, the first lower connection pad 114a may be electrically connected to the lower semiconductor chip 120 through the lower connection terminal 130. An external connection terminal 180 may be attached to the second lower connection pad 114b. The external connection terminal 180 may be, for example, a solder ball or a bump. The external connection terminal 180 may electrically connect the semiconductor package 1 to an electronic apparatus. A connection via 250 may be attached to the third lower connection pad 114c. The connection via 250 may electrically connect the lower sub-semiconductor package 100 to the upper sub-semiconductor package 300. For example, the upper sub-semiconductor package 300 may be electrically connected to the lower package base substrate 110 of the lower sub-semiconductor package 100 through the connection via 250.

The lower package base substrate 110 may further include a lower ground terminal 116 exposed at a side surface of the lower package base substrate 110. In FIG. 1A, the lower ground terminal 116 is exposed at a lower side surface of the lower package base substrate 110, but is not limited thereto. For example, the lower ground terminal 116 may be exposed at an upper side surface of the lower package base substrate 110 or throughout the side surface of the lower package base substrate 110.

An internal wire (not shown) provided between each of the at least one lower base layer 112 and a conductive via (not shown) penetrating the at least one lower base layer 112 may be provided in the lower package base substrate 110 so as to connect the first lower connection pad 114a, the second lower connection pad 114b, the third lower connection pad 114 and/or the lower ground terminal 116. According to some embodiments, a wire pattern (not shown) connecting the conductive via (not shown) and at least one of the first lower connection pad 114a, the second lower connection pad 114b, the third lower connection pad 114c, and/or the lower ground terminal 116 may be further provided on the top and/or bottom surfaces 110a and/or 110b of the lower package base substrate 110.

The first lower connection pad 114a, the second lower connection pad 114b, the third lower connection pad 114c, the lower ground terminal 116, the internal wire, and/or the wire pattern may be formed of, for example, electrolytically deposited (ED) copper foil, rolled-annealed (RA) copper foil, stainless steel foil, aluminum foil, ultra-thin copper foil, sputtered copper, or copper alloy. The conductive via may be formed of, for example, copper, nickel, stainless steel, or beryllium copper.

The lower semiconductor chip 120 may include a semiconductor substrate. The semiconductor substrate may include, for example, silicon (Si). In some embodiments, the semiconductor substrate may include a semiconductor element, such as germanium (Ge), or may include a compound semiconductor, such as silicon carbide (SiC), gallium arsenide (GaAs), indium arsenide (InAs), or indium phosphide (InP). The semiconductor substrate may have a silicon-on-insulator (SOI) structure. For example, the semiconductor substrate may include a buried oxide (BOX) layer. The semiconductor substrate may include a conductive region, for example, an impurity-doped well. The semiconductor substrate may have any one of various device isolation structures, such as a shallow trench isolation (STI) structure. The semiconductor substrate may have an active surface and a non-active surface opposite to the active surface.

In the lower semiconductor chip 120 may include a semiconductor device having a plurality of individual devices of various types formed on the active surface. Examples of the plurality of individual devices include various microelectronic devices, for example, a metal-oxide-semiconductor field effect transistor (MOSFET) such as a complementary metal-insulator-semiconductor (CMOS) transistor, a system large scale integration (LSI), an image sensor such as a CMOS imaging sensor (CIS), a micro-electro-mechanical system (MEMS), an active device, and a passive device. The plurality of individual devices may be electrically connected to the conductive region of the semiconductor substrate. The semiconductor device may further include a conductive wire or a conductive plug electrically connecting at least two of the plurality of individual devices or connecting the conductive region of the semiconductor substrate and the plurality of individual devices. Also, the plurality of individual devices may each be electrically separated from other neighboring individual devices by an insulating layer.

The lower semiconductor chip 120 may include a plurality of lower semiconductor pads (not shown) provided on the active surface. The lower connection terminal 130 may be attached on the plurality of lower semiconductor pads. Accordingly, the lower semiconductor chip 120 may be electrically connected to the lower package base substrate 110 through the lower connection terminal 130.

According to some embodiments, the lower semiconductor chip 120 may be on the lower package base substrate 110 in a flip-chip manner in which the active surface thereof faces the lower package base substrate 110. The lower connection terminal 130 may be between the active surface of the lower semiconductor chip 120 and the top surface 110a of the lower package base substrate 110. The lower connection terminal 130 may be, for example, a solder ball or a bump. The lower sub-semiconductor package 100 may further include an under-fill layer 140 on and/or surrounding the lower connection terminal 130 and filling between the active surface of the lower semiconductor chip 120 and the top surface 110a of the lower package base substrate 110. According to some embodiments, the under-fill layer 140 may be a molded under-fill (MUF) layer integrally formed with a lower mold layer 190 described below.

According to some embodiments, the lower semiconductor chip 120 may be provided on the lower package base substrate 110 such that the non-active surface thereof faces the lower package base substrate 110. The lower connection terminal 130 may be, for example, a bonding wire. In this case, a die attach film (DAF) may be provided between the non-active surface of the lower semiconductor chip 120 and the top surface 110a of the lower package base substrate 110, instead of the under-fill layer 140 of FIG. 1A.

In FIG. 1A, the lower sub-semiconductor package 100 includes one lower semiconductor chip 120, but is not limited thereto. For example, the lower sub-semiconductor package 100 may include a plurality of lower semiconductor chips 120 stacked on the lower package base substrate 110 in a vertical direction, or may include the plurality of lower semiconductor chips 120 provided on the lower package base substrate 110 in a horizontal direction.

According to some embodiments, the lower semiconductor chip 120 may be a central processing unit (CPU), a microprocessing unit (MPU), a graphics processing unit (GPU), and/or an application processor (AP). According to some embodiments, the lower semiconductor chip 120 may be a controller semiconductor chip for controlling an upper semiconductor chip 320 described below. According to some embodiments, the lower semiconductor chip 120 may be a volatile memory semiconductor chip, such as dynamic random access memory (DRAM) and/or static random access memory (SRAM). According to some embodiments, there may be a plurality of the lower semiconductor chips 120 each including the controller semiconductor chip for controlling the upper semiconductor chip 320 and the volatile memory semiconductor chip.

The lower mold layer 190 covering the top surface 110a of the lower package base substrate 110 and on and/or surrounding the lower semiconductor chip 120 may be provided on the lower package base substrate 110. The lower mold layer 190 may be formed of, for example, epoxy molding compound (EMC). The lower mold layer 190 may be encapsulating layer that encapsulates the semiconductor chip 120 to provide strength and/or protection.

The lower mold layer 190 may have a mold via hole 195 exposing the third lower connection pad 114c. The mold via hole 195 may penetrate from a top surface to a bottom surface of the lower mold layer 190. According to some embodiments, the mold via hole 195 may extend from the top surface to the bottom surface of the lower mold layer 190. The mold via hole 195 may have a tapered width shape.

The connection via 250 may be provided in the mold via hole 195. The connection via 250 may be formed of tin (Sn)-containing solder, palladium (Pd), nickel (Ni), silver (Ag), lead (Pb), or an alloy thereof. A bottom of the connection via 250 may be connected to the third lower connection pad 114c. The connection via 250 may extend towards the upper sub-semiconductor package 300 such that a top of the connection via 250 is higher than the top surface of the lower mold layer 190. The top of the connection via 250 may be connected to a second upper connection pad 314b of the upper sub-semiconductor package 300 described below. According to some embodiments, the connection via 250 may completely fill portions of the mold via hole 195 except for a partial upper portion of the connection via 250. In other words, the connection via 250 may not fill the partial upper portion of the mold via hole 195.

A filling layer 240 filling a space between the lower sub-semiconductor package 100 and the upper sub-semiconductor package 300 may be provided between the lower sub-semiconductor package 100 and the upper sub-semiconductor package 300. The filling layer 240 may include an insulating filler 225 and may be referred to as an insulating layer. The insulating filler 225 may absorb heat emitted from the lower semiconductor chip 120. The insulating filler 225 may be formed of a ceramic-based material having an insulating characteristic of non-conductivity. The insulating filler 225 may be formed of at least one of, for example, aluminum nitride (AlN), boron nitride (BN), aluminum oxide (Al₂O₃), silicon carbide (SiC), or magnesium oxide (MgO). The filling layer 240 may cover the top surface of the lower mold layer 190 and surround a part of an upper side surface of the connection via 250. According to some embodiments, the filling layer 240 may directly contact the top surface of the lower mold layer 190 and a bottom surface 310b of an upper package base substrate 310 so as to completely fill the space between the lower sub-semiconductor package 100 and the upper sub-semiconductor package 300.

The filling layer 240 may have an extending part 240t filling the partial upper portion of the mold via hole 195. The filling layer 240 may have a part having a level higher than the top surface of the lower mold layer 190, and the extending part 240t extending therefrom into the mold via hole 195. For example, the extending part 240t of the filling layer 240 may partially or fully fill the partial upper portion of the mold via hole 195, that is not filled by the connection via 250. The extending part 240t may extend into the mold via hole 195 and have a width decreasing tail shape based on a cross-section of the semiconductor package 1 in a vertical direction. In some embodiments, the extending part of the insulating layer may extend along a sidewall of the first connection via and/or along a sidewall of the second connection via from a portion of the insulating layer and/or filling layer 240 having a higher level than a top surface of the encapsulating layer and/or lower mold layer 190.

The filling layer 240 may be formed of, for example, an insulating film, tape, or paste. According to some embodiments, the filling layer 240 may be formed of a material capable of electromagnetic wave shielding.

The upper sub-semiconductor package 300 is provided over the lower sub-semiconductor package 100. The upper sub-semiconductor package 300 may be provided over the lower sub-semiconductor package 100 with the filling layer 240 therebetween. The lower sub-semiconductor package 100 and the upper sub-semiconductor package 300 may be electrically connected through the connection via 250. The connection via 250 may penetrate the lower mold layer 190 and the filling layer 240 to connect the bottom surface 310b of the upper package base substrate 310 of the upper sub-semiconductor package 300 to the top surface 110a of the lower package base substrate 110 of the lower sub-semiconductor package 100.

The connection via 250 may have a widest width at an end portion of the extending part 240t of the filling layer 240, i.e., at a lowermost end of the extending part 240t extending into the mold via hole 195. According to some embodiments, the connection via 250 may extend as a width increases upward from a lowermost end thereof, i.e., at a region contacting the third lower connection pad 114c, and have the widest width at a region contacting the lowermost end of the extending part 240t. The connection via 250 may extend as a width decreases upward from the region contacting the extending part 240t, and may contact the second upper connection pad 314b.

In other words, the connection via 250 may have the widest width inside the mold via hole 195, i.e., a level lower than the top surface of the lower mold layer 190.

The upper sub-semiconductor package 300 may include the upper package base substrate 310 and the upper semiconductor chip 320 provided on the upper package base substrate 310.

According to some embodiments, the upper package base substrate 310 may be a printed circuit board. The upper package base substrate 310 may include at least one upper base layer 312, and a plurality of upper connection pads provided on a top surface 310a and the bottom surface 310b of the upper package base substrate 310. An upper solder resist layer 318 may be provided on a top surface and a bottom surface of the upper base layer 312. The plurality of upper connection pads may not be covered by the upper solder resist layer 318, but may be exposed at the top and bottom surfaces 310a and 310b of the upper package base substrate 310. According to some embodiments, the upper solder resist layer 318 may be provided only on the bottom surface of the upper base layer 312, and may not be provided on the top surface thereof. According to some embodiments, the upper package base substrate 310 may include a plurality of the upper base layers 312 that are stacked on each other.

The plurality of upper connection pads may include a first upper connection pad 314a and the second upper connection pad 314b. The first upper connection pad 314a may be on the top surface 310a of the upper package base substrate 310, and the second upper connection pad 314b may be on the bottom surface 310b of the upper package base substrate 310.

An end of an upper connection terminal 330 may be connected to the upper semiconductor chip 320, and the other end of the upper connection terminal 330 may be connected to the first upper connection pad 314a. Accordingly, the first upper connection pad 314a and the upper semiconductor chip 320 may be electrically connected through the upper connection terminal 330. For example, the upper connection terminal 330 may be bonding wire.

The connection via 250 may be physically and/or electrically connected to the second upper connection pad 314b. A top surface of the connection via 250 may contact the second upper connection pad 314b and a bottom surface of the connection via 250 may contact the third lower connection pad 114c.

The upper package base substrate 310 may further include an upper ground terminal 316 exposed at a side surface. In FIG. 1A, the upper ground terminal 316 is exposed at a lower side surface of the upper package base substrate 310, but is not limited thereto. For example, the upper ground terminal 316 may be exposed at an upper side surface of the upper package base substrate 310 or may be exposed throughout the side surface of the upper package base substrate 310.

According to some embodiments, one of the lower ground terminal 116 or the upper ground terminal 316 may be omitted. In other words, the semiconductor package 1 may include a ground terminal at only one of the lower package base substrate 110 or the upper package base substrate 310.

A structure of the upper package base substrate 310 is similar to that of the lower package base substrate 110 described above, and thus details thereof are not provided.

The upper semiconductor chip 320 may include a semiconductor substrate. A structure of the upper semiconductor chip 320 is similar to that of the lower semiconductor chip 120, and thus details thereof are not provided. According to some embodiments, the upper semiconductor chip 320 may have a horizontal area larger than the lower semiconductor chip 120.

The upper semiconductor chip 320 may be, for example, a memory semiconductor chip. The memory semiconductor chip may be, for example, a nonvolatile memory semiconductor chip, such as a flash memory, phase-change random access memory (PRAM), magnetoresistive random access memory (MRAM), ferroelectric random access memory (FeRAM), or resistive random access memory (RRAM). The flash memory may be, for example, a V-NAND flash memory.

The upper sub-semiconductor package 300 may include at least one upper semiconductor chip 320. For example, the upper sub-semiconductor package 300 may include a plurality of the upper semiconductor chips 320. According to some embodiments, the plurality of upper semiconductor chips 320 may form a stack of a plurality of memory semiconductor chips. According to the JEDEC standard definition, the term ‘stack’ may denote memory chips in a memory system taken together in one assembly. In this case, each of the plurality of upper semiconductor ships 320 may be a slice. According to the JEDEC standard definition, the term ‘slice’ may denote one memory chip in a stack of memory chips.

According to some embodiments, the upper semiconductor chip 320 has a die attach film (DAF) 322 attached on a bottom surface thereof, and may be attached to a structure therebelow. For example, the lowermost upper semiconductor chip 320 from among the plurality of upper semiconductor chips 320 has the DAF 322 and may be attached on the upper package base substrate 310, and the remaining upper semiconductor chips 320 have the DAFs 322 and attached on the other upper semiconductor chips 320 respectively below.

The DAF 322 may be formed of, for example, a mineral adhesive or a polymer adhesive. The polymer adhesive may be formed of, for example, thermosetting polymer or thermoplastic polymer. In the thermosetting polymer, the monomer has a cross-link structure after thermoforming, and may not be softened when re-heated. On the other hand, the thermoplastic polymer is a polymer having plasticity by heat, and has a linear polymer structure. Also, the polymer adhesive may be a hybrid type by mixing the thermosetting polymer and the thermoplastic polymer.

In FIG. 1A, the plurality of upper semiconductor chips 320 are stacked in a stepped shape, but are not limited thereto. For example, the plurality of upper semiconductor chips 320 may be stacked overlapping each other in a perpendicular direction with respect to the upper package base substrate 310.

According to some embodiments, the upper sub-semiconductor package 300 may further include a controller semiconductor chip (not shown) for controlling the at least one upper semiconductor chip 320.

A controller (not shown) may be embedded in the controller semiconductor chip. The controller may control access to data stored in the nonvolatile memory semiconductor chip. In other words, the controller may control write/read operations of the nonvolatile memory semiconductor chip, for example, a flash memory, according to a control command of an external host. According to some embodiments, the controller may be configured as a separate control semiconductor chip, such as an application specific integrated circuit (ASIC). The controller may perform wear leveling, garbage collection, bad block management, and/or determine an error correcting code (ECC) for the nonvolatile memory semiconductor chip.

An upper mold layer 390 covering the top surface 310a of the upper package base substrate 310 and surrounding and/or on the upper semiconductor chip 320 and the upper connection terminal 330 may be provided on the upper package base substrate 310. The upper mold layer 390 may be formed of, for example, epoxy molding compound (EMC).

The semiconductor package 1 may include the electromagnetic wave shielding member 400 covering at least some of surfaces of the lower and upper sub-semiconductor packages 100 and 300. The electromagnetic wave shielding member 400 may also cover the top and side surfaces of the upper sub-semiconductor package 300 and/or the side surface of the lower sub-semiconductor package 100. According to some embodiments, the electromagnetic wave shielding member 400 may also cover some of the bottom surface of the lower sub-semiconductor package 100. For example, the electromagnetic wave shielding member 400 may cover the side surface of the lower package base substrate 110, the side surface of the lower mold layer 190, the side surface of the upper package base substrate 310, and/or the side and top surfaces of the upper mold layer 390. According to some embodiments, the electromagnetic wave shielding member 400 may also cover some of the bottom surface 110b of the lower package base substrate 110.

The electromagnetic wave shielding member 400 may be formed by, for example, a physical vapor deposition (PVD) method. According to some embodiments, the electromagnetic wave shielding member 400 may be formed by a sputtering process. For example, the electromagnetic wave shielding member 400 may include a metal material, such as Cu or Ag.

When the semiconductor package 1 is mounted on an electronic apparatus that includes other electronic components, electromagnetic waves generated in the semiconductor package 1 may be emitted to cause electromagnetic interference (EMI) in another electronic component mounted in the electronic apparatus. Additionally or alternatively, electromagnetic waves generated and/or emitted in another electronic component mounted in the electronic apparatus may be emitted to cause EMI in the semiconductor package 1. Accordingly, disorder, such as electromagnetic wave noise or malfunction, occurs in the electronic apparatus on which the semiconductor package 1 is mounted, and thus reliability of a product deteriorates. In this regard, the electromagnetic wave shielding member 400 may prevent and/or inhibit electronic waves inevitably generated during operations of the semiconductor package 1 and/or the other electronic components of the electronic apparatus from affecting the other electronic component and/or the semiconductor package 1.

The electromagnetic wave shielding member 400 may contact and be electrically connected to the lower and upper ground terminals 116 and 316. The lower and upper ground terminals 116 and 316 may be electrically connected to the external connection terminal 180 that provides ground connection. Accordingly, the electromagnetic wave shielding member 400 may be grounded to an external source.

According to some embodiments, when the semiconductor package 1 only includes one of the lower and upper ground terminals 116 and 316, the electromagnetic wave shielding member 400 may contact and be electrically connected to the one of the lower and upper ground terminals 116 and 316.

The semiconductor package 1 according to some embodiments includes the filling layer 240 filling a space between the lower and upper sub-semiconductor packages 100 and 300. Accordingly, while forming the electromagnetic wave shielding member 400, a metal material forming the electromagnetic wave shielding member 400 may be prevented and/or inhibited from penetrating the space between the lower and upper sub-semiconductor packages 100 and 300 due to the presence of the filling layer 240.

If the semiconductor package 1 does not include the filling layer 240, the lower and upper sub-semiconductor packages 100 and 300 may have a gap due to the connection via 250. The gap between the lower and upper sub-semiconductor packages 100 and 300 may be due to a portion of the connection via 250 extending beyond the mold via hole 195. In this case, during formation of the electromagnetic wave shielding member 400, the metal material forming the electromagnetic wave shielding member 400 may penetrate the gap between the lower and upper sub-semiconductor packages 100 and 300, causing a short circuit to occur between the different connection vias 250. In other words, two or more connection vias 250 may be electrically shorted together by metal material used in the formation of the electromagnetic wave shielding member 400.

However, in the semiconductor package 1 according to some embodiments, the filling layer 240 prevents and/or inhibits the metal material forming the electromagnetic wave shielding member 400 from penetrating the space between the lower and upper sub-semiconductor packages 100 and 300, thereby preventing and/or inhibiting a short circuit between the adjacent connection vias 250. Thus electrical reliability of the semiconductor package 1 may be increased by the presence of the filling layer 240.

Also, in the semiconductor package 1 according to some embodiments, the extending part 240t, i.e., a part of the filling layer 240, extends into the mold via hole 195 to fill the partial upper portion of the mold via hole 195. The extending part 240t, i.e., the part of the filling layer 240, may decrease a width of the upper portion of the connection via 250. Accordingly, the filling layer 240 prevents and/or inhibits the width of the upper portion of the connection via 250 from increasing or prevents and/or inhibits the connection via 250 from extending to a peripheral region along the top surface of the lower mold layer 190 while forming the connection via 250 to prevent and/or inhibit a short circuit between adjacent connection vias 250. Thus electrical reliability of the semiconductor package 1 may be increased.

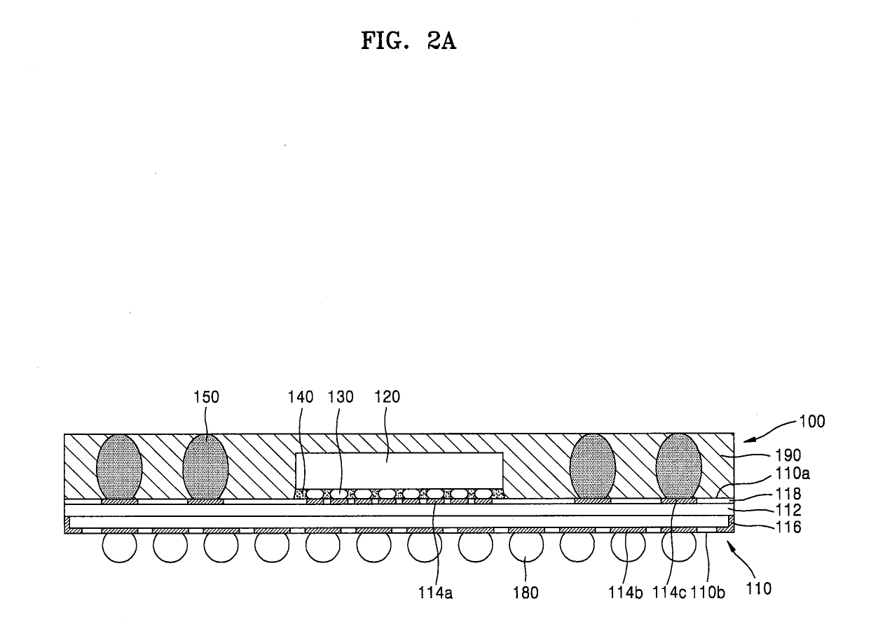

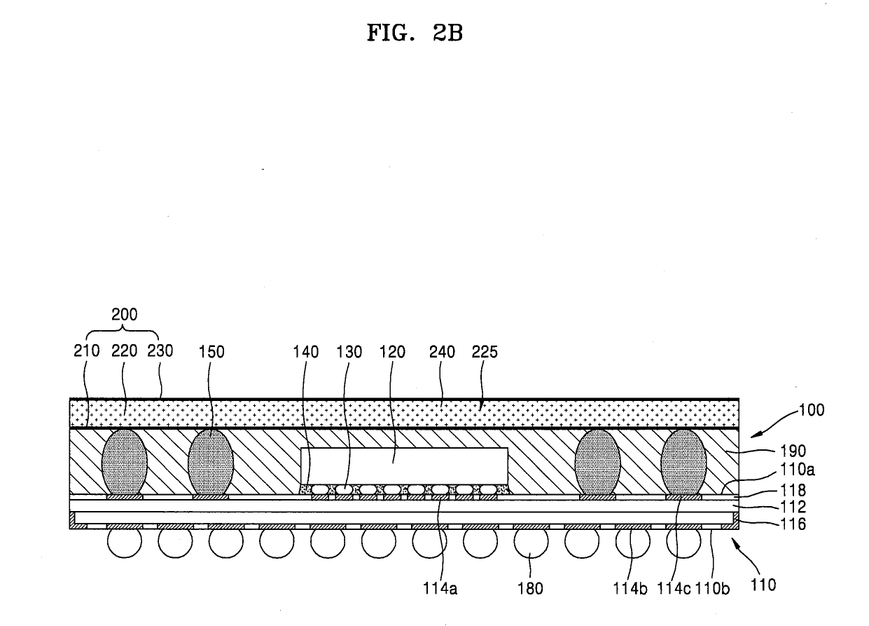

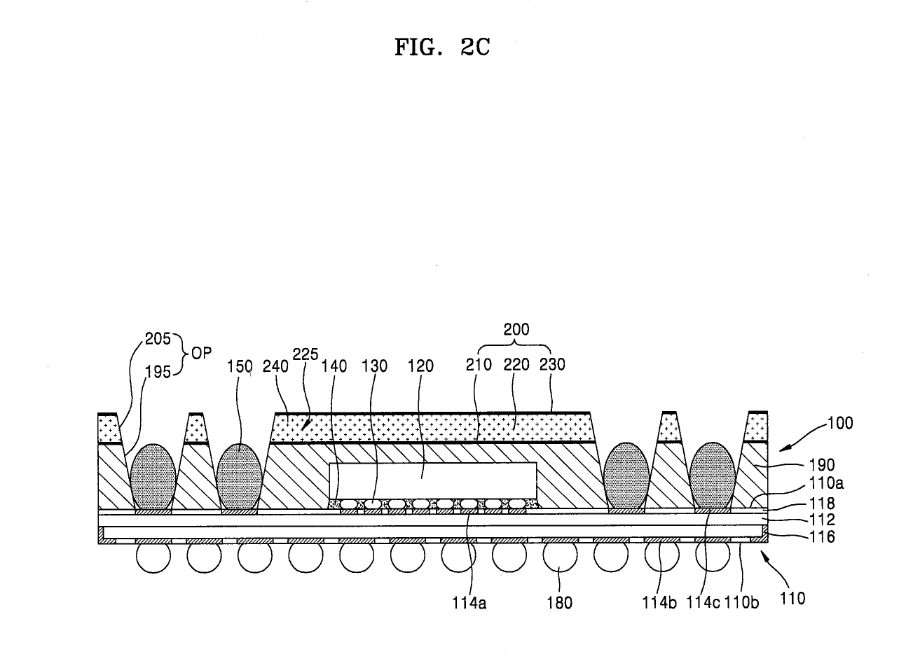

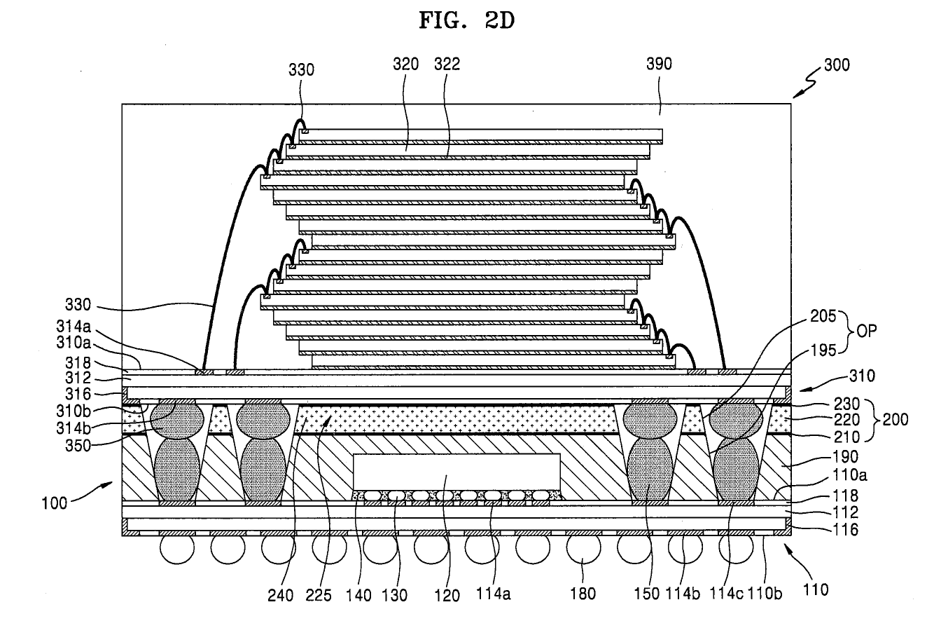

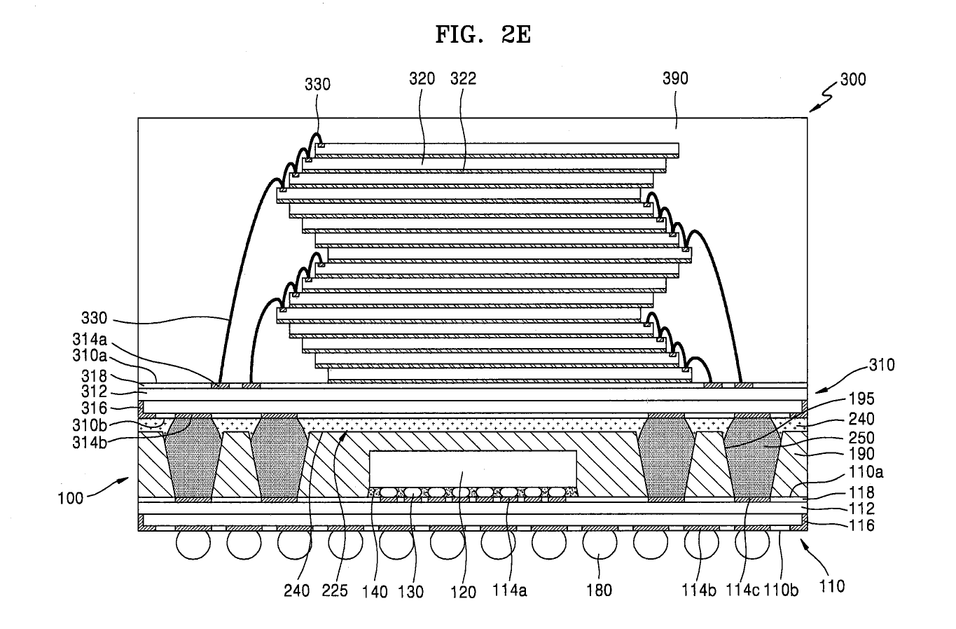

FIGS. 2A through 2E are cross-sectional views for describing a method of manufacturing a semiconductor package, according to some embodiments. Descriptions about FIGS. 2A through 2E, which overlap those of FIG. 1A, may not be provided again.

Referring to FIG. 2A, the lower sub-semiconductor package 100 is prepared. The lower sub-semiconductor package 100 may include the lower package base substrate 110 and the lower semiconductor chip 120 on the lower package base substrate 110.

The lower package base substrate 110 includes at least one lower base layer 112, the first and third lower connection pads 114a and 114c on the top surface 110a of the lower package base substrate 110, and the second lower connection pad 114b on the bottom surface 110b of the lower package base substrate 110. The lower package base substrate 110 may further include the lower ground terminal 116 exposed at the side surface.

The lower connection terminal 130 attached to the lower semiconductor chip 120 may be connected to the first lower connection pad 114a. The external connection terminal 180 may be connected to the second lower connection pad 114b. A lower connection via 150 may be connected to the third lower connection pad 114c.

The lower sub-semiconductor package 100 may include the under-fill layer 140 on and/or surrounding the lower connection terminal 130 and fill between the bottom surface of the lower semiconductor chip 120 and the top surface 110a of the lower package base substrate 110. The under-fill layer 140 may prevent and/or inhibit extraneous particles such as pieces of metal from the process from contacting the lower connection terminal 130.

The lower mold layer 190 covering the top surface 110a of the lower package base substrate 110 and/or surrounding the lower semiconductor chip 120 and the lower connection via 150 may be on the lower package base substrate 110. The lower mold layer 190 may cover the top and/or side surfaces of the lower semiconductor chip 120.

According to some embodiments, the top of the lower connection via 150 may be exposed at the top surface of the lower mold layer 190, but is not limited thereto. For example, the lower mold layer 190 may cover both the top and side surfaces of the lower connection via 150.

Referring to FIG. 2B, an adhesive layer 200 may be attached on the lower sub-semiconductor package 100. The adhesive layer 200 may be placed on the lower sub-semiconductor package 100 to cover the top surface of the lower mold layer 190. The adhesive layer 200 may be formed by attaching an insulating film or tape on the lower sub-semiconductor package 100 or by placing a coating paste on the lower sub-semiconductor package 100. According to some embodiments, the adhesive layer 200 may be formed by attaching an adhesive film on the top surface of the lower mold layer 190. According to some embodiments, the adhesive layer 200 may be formed by attaching a tape on the top surface of the lower mold layer 190, wherein the tape includes a core layer 220 and lower and upper adhesive layers 210 and 230 provided respectively on bottom and top surfaces of the core layer 220. According to some embodiments, the core layer 220 may include the insulating filler 225. The insulating filler 225 may be formed of a ceramic-based material having an insulating characteristic of non-conductivity. The insulating filler 225 may be formed of, for example, at least one of AlN, BN, Al₂O₃, SiC, or MgO. According to some embodiments, the adhesive layer 200 may be formed by coating paste having an adhesive property on the top surface of the lower mold layer 190.

Referring to FIG. 2C, parts of the adhesive layer 200 and the lower mold layer 190 may be removed to form an opening OP penetrating the adhesive layer 200 and the lower mold layer 190. The opening OP may include the mold via hole 195 penetrating the lower mold layer 190 and an adhesive via hole 205 penetrating the adhesive layer 200. The lower connection via 150 may be exposed inside the opening OP. In other words, the opening OP may be formed by removing a part of the adhesive layer 200 and a part of the lower mold layer 190 around the lower connection via 150 such that the lower connection via 150 is exposed.

According to some embodiments, the opening OP may be formed by a laser drilling method.

Referring to FIG. 2D, the upper, sub-semiconductor package 300 may be on the lower sub-semiconductor package 100. The upper sub-semiconductor package 300 may be attached on the lower sub-semiconductor package 100 by the adhesive layer 200.

The upper sub-semiconductor package 300 may include the upper package base substrate 310 and the upper semiconductor chip 320 provided on the upper package base substrate 310.

The upper package base substrate 310 may include at least one upper base layer 312, the first upper connection pad 314a provided on the top surface 310a of the upper package base substrate 310, and the second upper connection pad 314b provided on the bottom surface 310b. The upper package base substrate 310 may further include the upper ground terminal 316 exposed at the side surface.

An end of an upper connection terminal 330 may be connected to the upper semiconductor chip 320, and the other end of the upper connection terminal 330 may be connected to the first upper connection pad 314a. An upper connection via 350 may be connected to the second upper connection pad 314b.

The upper semiconductor chip 320 may have DAF 322 on a bottom surface, and may be connected to a structure therebelow.

The upper mold layer 390 that covers the top surface 310a of the upper package base substrate 310 and surrounding the upper semiconductor chip 320 and the upper connection terminal 330 may be provided on the upper package base substrate 310.

The upper connection via 350 may be attached to a part of the bottom surface 310b of the upper package base substrate 310, which corresponds to the opening OP. The upper sub-semiconductor package 300 may be on the lower sub-semiconductor package 100 such that the upper connection via 350 is at least partially or fully in the opening OP. Accordingly, the upper and/or lower connection vias 350 and 150 may be located in the opening OP.

According to some embodiments, the upper sub-semiconductor package 300 may be on the lower sub-semiconductor package 100 such that the upper connection via 350 contacts the corresponding lower connection via 150, but is not limited thereto. For example, the upper and lower connection vias 350 and 150 may not contact each other in the opening OP. In other words, the bottom of the upper connection via 350 and the top of the lower connection via 150 may be spaced apart from each other. According to some embodiments, the lower connection via 150 may be omitted when the upper connection via 350 has a height sufficient to form the connection via 250 of FIGS. 1A and 1B contacting the third lower connection pad 114c.

Referring to FIGS. 2D and 2E, heat may be applied to the lower and upper sub-semiconductor packages 100 and 300, or heat and pressure may be applied to the lower and upper sub-semiconductor packages 100 and 300 such that the lower connection via 150 and the upper connection via 350 are melted. Then, the connection via 250 may be formed as the lower and upper connection vias 150 and 350 are combined via a cooling process.

While the connection via 250 is formed, a part of the adhesive layer 200 may also be melted and may flow into the mold via hole 195. Then, the filling layer 240 may be formed from the adhesive layer 200 via a cooling process.

The melted part of the adhesive layer 200, which flowed into the mold via hole 195, may be the extending part 240t of the filling layer 240. The filling layer 240 may fill the space between the lower and upper sub-semiconductor packages 100 and 300. The extending part 240t of the filling layer 240 may fill a part of the mold via hole 195, which is not filled by the connection via 250. Accordingly, an interval between the top surface of the lower sub-semiconductor package 100 and the bottom surface of the upper sub-semiconductor package 300 may have a value lower than a value of a thickness of the adhesive layer 200. According to some embodiments, the distance between the top surface of the lower sub-semiconductor package 100 and the bottom surface of the upper sub-semiconductor package 300 may be between 10 μm to 100 μm.

When the lower and upper connection vias 150 and 350 are melted, a lower portion of the mold via hole 195 is first filled, and thus the melted part of the adhesive layer 200 may decrease the width of the upper portion of the opening OP. Also, the melted part of the adhesive layer 200, which flowed into the mold via hole 195, may fill the partial upper portion of the molded via hole 195.

Accordingly, the extending part 240t of the filling layer 240 may fill the partial upper portion of the mold via hole 195, which is not filled by the connection via 250.

According to some embodiments, the side surface of the lower sub-semiconductor package 100, the side surface of the filling layer 240, and the side surface of the upper sub-semiconductor package 300 in the same direction may be coplanar.

As such, the width of the upper portion of the connection via 250 may be smaller than the width of the upper portion of the opening OP. Accordingly, the filling layer 240 prevents and/or inhibits the width of the upper portion of the connection via 250 from increasing or prevents and/or inhibits the connection via 250 from extending to a peripheral region along the top surface of the lower mold layer 190 while the connection via 250 is formed, thereby preventing a short of the adjacent connection vias 250.

Then, referring back to FIG. 1A, the electromagnetic wave shielding member 400 covering the side surface of the lower package base substrate 110, the side surface of the lower mold layer 190, the side surface of the filling layer 240, the side surface of the upper package base substrate 310, and/or the side and/or top surfaces of the upper mold layer 390 is formed.

Since the filling layer 240 fills the space between the lower and upper sub-semiconductor packages 100 and 300, a metal material forming the electromagnetic wave shielding member 400 may be prevented from penetrating the space between the lower and upper sub-semiconductor packages 100 and 300 while the electromagnetic wave shielding member 400 is formed. Accordingly, the adjacent connection vias 250 may be prevented from being shorted by the metal material forming the electromagnetic wave shielding member 400.

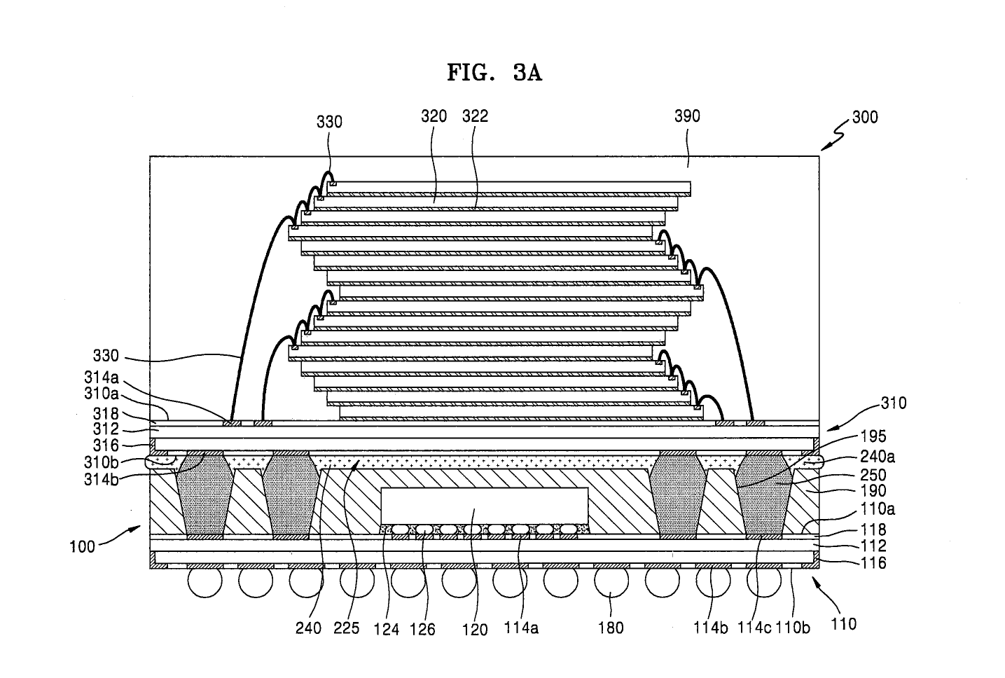

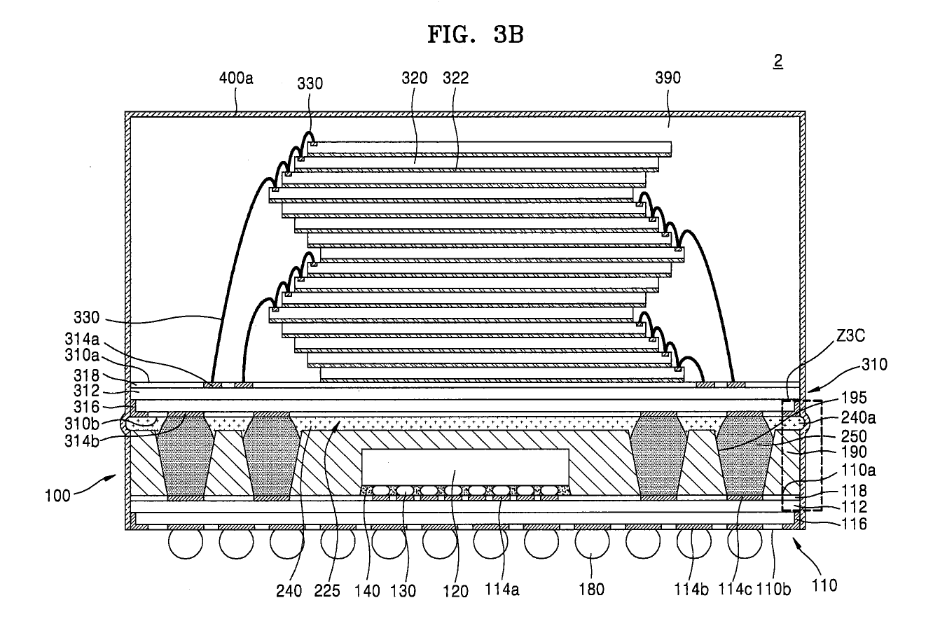

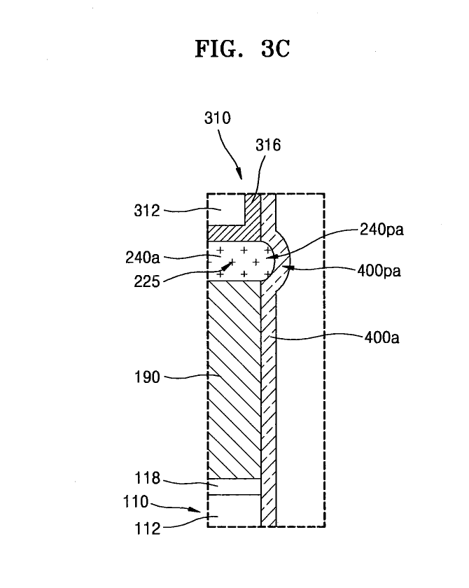

FIG. 3A is a cross-sectional view for describing a method of manufacturing a semiconductor package, according to some embodiments. For example, the FIG. 3A is a cross-sectional view for describing an operation performed after the operation of FIG. 2D. Details of FIG. 3A overlapping those of FIGS. 2A through 2E may not be provided.

Referring to FIGS. 2D and 3A together, heat and pressure are applied to the lower and upper sub-semiconductor packages 100 and 300 to melt the lower and upper connection vias 150 and 350. Then, the connection via 250 may be formed as the lower and upper connection vias 150 and 350 are combined via a cooling process.

While the connection via 250 is formed, a part of the adhesive layer 200 may also be melted and may flow into the mold via hole 195. Then, a filling layer 240a may be formed from the adhesive layer 200 after a cooling process.

FIGS. 3B and 3C are respectively a cross-sectional view and a partially enlarged cross-sectional view of a semiconductor package 2 according to some embodiments. For example, FIG. 3C is an enlarged cross-sectional view of a region Z3C of FIG. 3B.

When relatively large pressure is applied to the lower and upper sub-semiconductor packages 100 and 300, a part of the filling layer 240a may become a protruding part 240pa of FIG. 3C that protrudes farther than the side surfaces of the lower and upper sub-semiconductor packages 100 and 300. In other words, the side surface of the filling layer 240a may protrude farther than the side surfaces of the lower and upper sub-semiconductor packages 100 and 300 in the same direction.

According to some embodiments, when a semiconductor package is formed by a singulation process in which a plurality of semiconductor packages are manufactured together and then sawed, the filling layer 240 may be coplanar with the side surfaces of the lower and upper sub-semiconductor package 100 and 300 as shown in FIGS. 1A and 2E.

Referring to FIGS. 3B and 3C together, an electromagnetic wave shielding member 400a covering the side surface of the lower package base substrate 110, the side surface of the lower mold layer 190, the side surface of the filling layer 240a, the side surface of the upper package base substrate 310, and the side and top surfaces of the upper mold layer 390 is formed.

Since the filling layer 240a fills the space between the lower and upper sub-semiconductor packages 100 and 300, a metal or other material forming the electromagnetic wave shielding member 400a may be prevented from penetrating the space between the lower and upper sub-semiconductor packages 100 and 300 while the electromagnetic wave shielding member 400a is formed.

Also, since the filling layer 240a has the protruding part 240pa protruding farther than the side surfaces of the lower and upper sub-semiconductor packages 100 and 300 in the same direction, each of a boundary portion between the side surfaces of the lower sub-semiconductor package 100 and the filling layer 240a and a boundary portion between the side surface of the upper sub-semiconductor package 300 and the filling layer 240a has a relatively small space. Thus, while the electromagnetic wave shielding member 400a is formed, the metal material forming the electromagnetic wave shielding member 400a may be prevented from penetrating an interface between the lower sub-semiconductor package 100 and the filling layer 240a and an interface between the upper sub-semiconductor package 300 and the filling layer 240a.

Accordingly, the adjacent connection vias 250 may be prevented from being shorted by the metal material forming the electromagnetic wave shielding member 400a.

The electromagnetic wave shielding member 400a may have a shielding protruding part 400pa covering the surface of the protruding part 240pa. According to some embodiments, the shielding protruding part 400pa may have an arc shape on a cross-section of the semiconductor package 2 in a vertical direction.

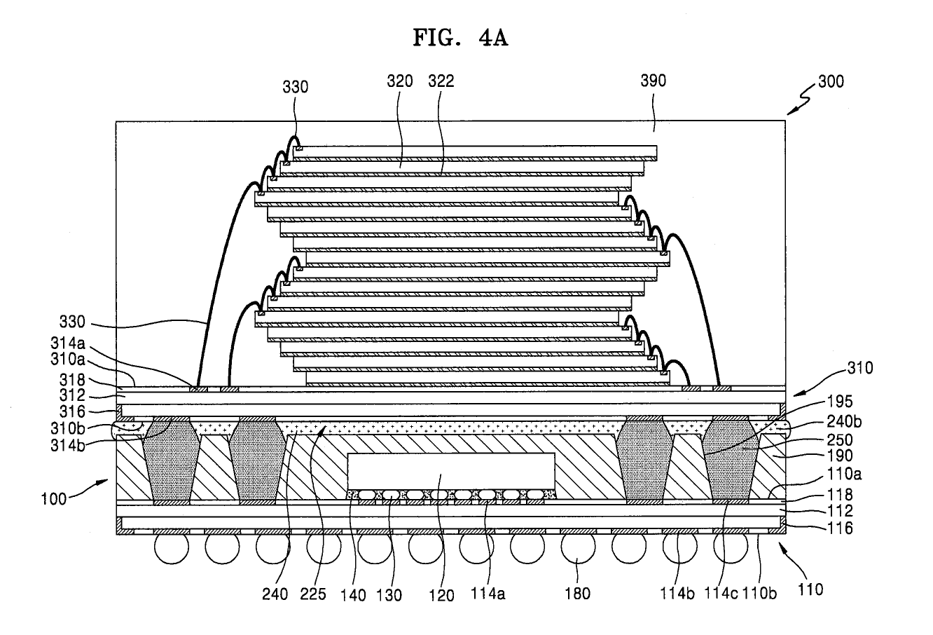

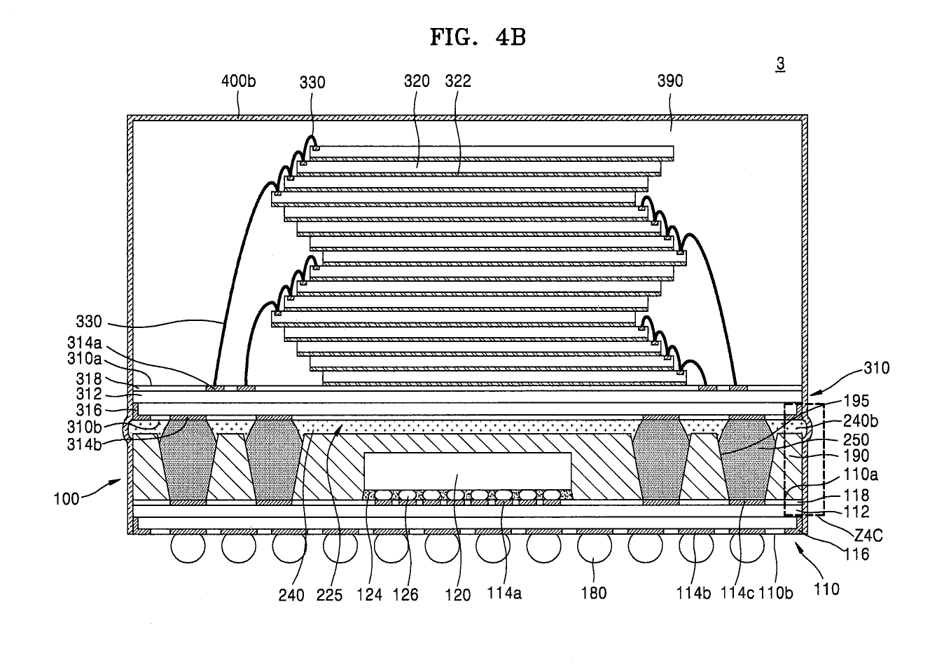

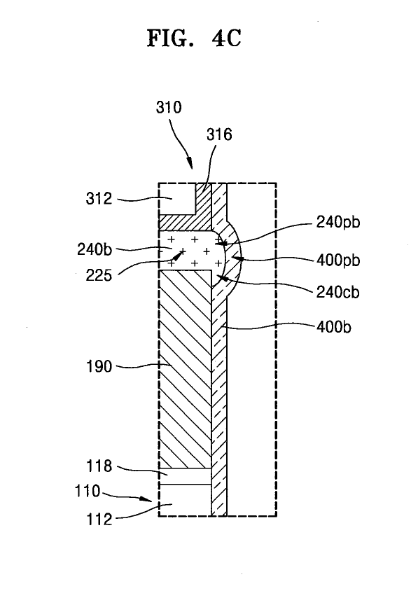

FIG. 4A is a cross-sectional view for describing a method of manufacturing a semiconductor package, according to some embodiments. For example, FIG. 4A is a cross-sectional view for describing an operation performed after the operation of FIG. 2D. Details of FIG. 4A overlapping those of FIGS. 2A through 2E may not be provided.

Referring to FIGS. 2D and 4A together, heat and pressure are applied to the lower and upper sub-semiconductor packages 100 and 300 to melt the lower and upper connection vias 150 and 350. Then, the connection via 250 may be formed as the lower and upper connection vias 150 and 350 are combined via a cooling process.

While the connection via 250 is formed, a part of the adhesive layer 200 may also be melted and may flow into the mold via hole 195. Then, a filling layer 240b may be formed from the adhesive layer 200 after a cooling process.

FIGS. 4B and 4C are respectively a cross-sectional view and a partially enlarged cross-sectional view of a semiconductor package 3 according to some embodiments. For example, FIG. 4C is an enlarged cross-sectional view of a region Z4C of FIG. 4B.

When a relatively large pressure is applied to the lower and upper sub-semiconductor packages 100 and 300, a part of the filling layer 240b may become a protruding part 240pb of FIG. 4C that protrudes farther than the side surfaces of the lower and upper sub-semiconductor packages 100 and 300. The protruding part 240pb may further have a lower covering part 240cb of FIG. 4C covering the partial upper portion of the side surface of the lower sub-semiconductor package 100. The side surface of the filling layer 240b may protrude farther than the side surfaces of the lower and/or upper sub-semiconductor packages 100 and 300 in the same direction. A part of the filling layer 240b may cover the partial upper portion of the side surface of the lower sub-semiconductor package 100, such as for example, the partial upper portion of the side surface of the lower mold layer 190. The filling layer 240b may not cover at least a part of the lower ground terminal 116 exposed at the side surface of the lower package base substrate 110.

Referring to FIGS. 4B and 4C together, an electromagnetic wave shielding member 400b covering the side surface of the lower package base substrate 110, the side surface of the lower mold layer 190, the side surface of the filling layer 240b, the side surface of the upper package base substrate 310, and/or the side and top surfaces of the upper mold layer 390 may be formed.

Since the filling layer 240b fills the space between the lower and upper sub-semiconductor packages 100 and 300, a metal material forming the electromagnetic wave shielding member 400b may be prevented from penetrating the space between the lower and upper sub-semiconductor packages 100 and 300 while the electromagnetic wave shielding member 400b is formed.

Since the filling layer 240b has the protruding part 240pb protruding farther than the side surfaces of the lower and upper sub-semiconductor packages 100 and 300 in the same direction, while the electromagnetic wave shielding member 400b is formed, the metal material forming the electromagnetic wave shielding member 400b may be prevented from penetrating an interface between the upper sub-semiconductor package 300 and the filling layer 240b.

Since the filling layer 240b further has the lower covering part 240cb covering the partial upper portion of the side surface of the lower sub-semiconductor package 100, while the electromagnetic wave shielding member 400b is formed, the metal material forming the electromagnetic wave shielding member 400b may be prevented from penetrating an interface between the lower sub-semiconductor package 100 and the filling layer 240b and/or 240cb.

Accordingly, the adjacent connection vias 250 may be prevented from being shorted by the metal material forming the electromagnetic wave shielding member 400b.

The electromagnetic wave shielding member 400b may have a shielding protruding part 400pb covering the surfaces of the protruding part 240pb and/or the lower covering part 240cb. According to some embodiments, the shielding protruding part 400pb may have an arc shape on a cross-section of the semiconductor package 3 in a vertical direction.

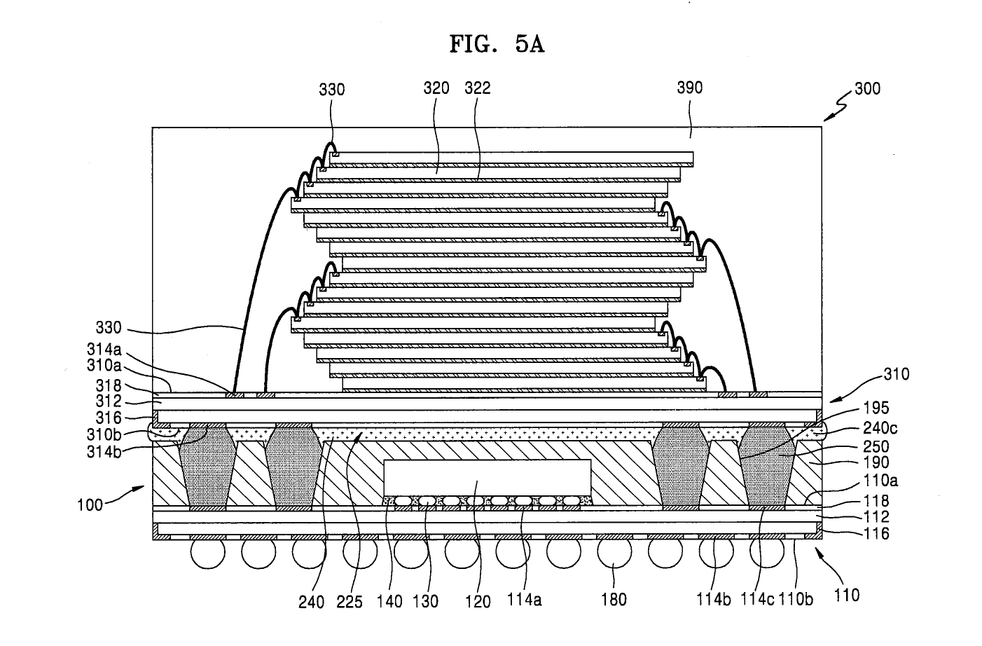

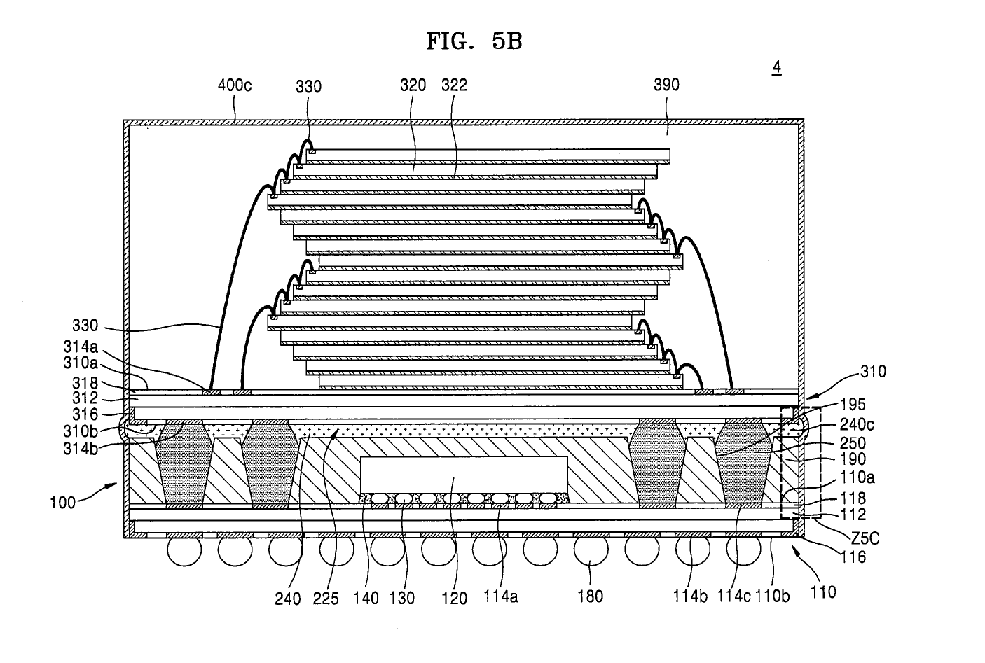

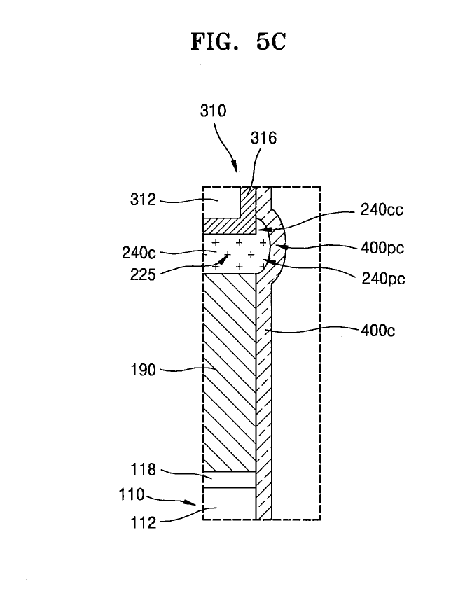

FIG. 5A is a cross-sectional view for describing a method of manufacturing a semiconductor package, according to some embodiments. For example, FIG. 5A is a cross-sectional view for describing an operation performed after the operation of FIG. 2D, and details of FIG. 5A overlapping those of FIGS. 2A through 2E may not be provided.

Referring to FIGS. 2D and 5A together, heat and pressure are applied to the lower and upper sub-semiconductor packages 100 and 300 to melt the lower and upper connection vias 150 and 350. Then, the connection via 250 may be formed as the lower and upper connection vias 150 and 350 are combined via a cooling process.

While the connection via 250 is formed, a part of the adhesive layer 200 may also be melted and may flow into the mold via hole 195. Then, a filling layer 240c may be formed from the adhesive layer 200 after a cooling process.

FIGS. 5B and 5C are respectively a cross-sectional view and a partially enlarged cross-sectional view of a semiconductor package 4 according to some embodiments. For example, FIG. 5C is an enlarged cross-sectional view of a region Z5C of FIG. 5B.

When a relatively large pressure is applied to the lower and upper sub-semiconductor packages 100 and 300, a part of the filling layer 240c may become a protruding part 240pc of FIG. 5C that protrudes farther than the side surfaces of the lower and upper sub-semiconductor packages 100 and 300. The protruding part 240pc may further have an upper covering part 240cc of FIG. 5C covering the partial lower portion of the side surface of the upper sub-semiconductor package 300. In other words, the side surface of the filling layer 240c may protrude farther than the side surfaces of the lower and upper sub-semiconductor packages 100 and 300 in the same direction, and a part of the filling layer 240c may cover the partial lower portion of the side surface of the upper sub-semiconductor package 300, for example, the partial lower portion of the side surface of the upper package base substrate 310. The filling layer 240c may not cover at least a part of the upper ground terminal 316 exposed at the side surface of the upper package base substrate 310.

Referring to FIGS. 5B and 5C together, an electromagnetic wave shielding member 400c covering the side surface of the lower package base substrate 110, the side surface of the lower mold layer 190, the side surface of the filling layer 240c, the side surface of the upper package base substrate 310, and/or the side and/or top surfaces of the upper mold layer 390 is formed.

Since the filling layer 240c fills the space between the lower and upper sub-semiconductor packages 100 and 300, a metal material forming the electromagnetic wave shielding member 400c may be prevented from penetrating the space between the lower and upper sub-semiconductor packages 100 and 300 while the electromagnetic wave shielding member 400c is formed.

Since the filling layer 240c has protruding part 240pc protruding farther than the side surfaces of the lower and upper sub-semiconductor packages 100 and 300 in the same direction, while the electromagnetic wave shielding member 400c is formed, the metal material forming the electromagnetic wave shielding member 400c may be prevented from penetrating an interface between the upper sub-semiconductor package 300 and the filling layer 240c.

Also, since the filling layer 240c further has the upper covering part 240cc covering the partial lower portion of the side surface of the upper sub-semiconductor package 300, while the electromagnetic wave shielding member 400c is formed, the metal material forming the electromagnetic wave shielding member 400c may be prevented from penetrating an interface between the upper sub-semiconductor package 300 and the filling layer 240c.

Accordingly, the adjacent connection vias 250 may be prevented from being shorted by the metal material forming the electromagnetic wave shielding member 400c.

The electromagnetic wave shielding member 400c may have a shielding protruding part 400pc covering the surfaces of the protruding part 240pc and the upper covering part 240cc. According to some embodiments, the shielding protruding part 400pc may have an arc shape on a cross-section of the semiconductor package 4 in a vertical direction.

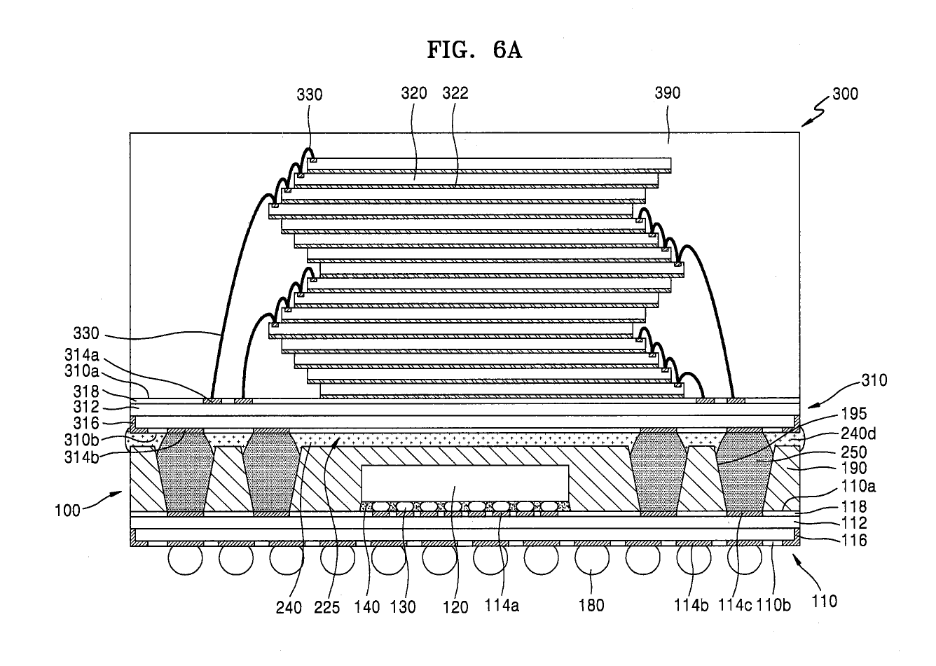

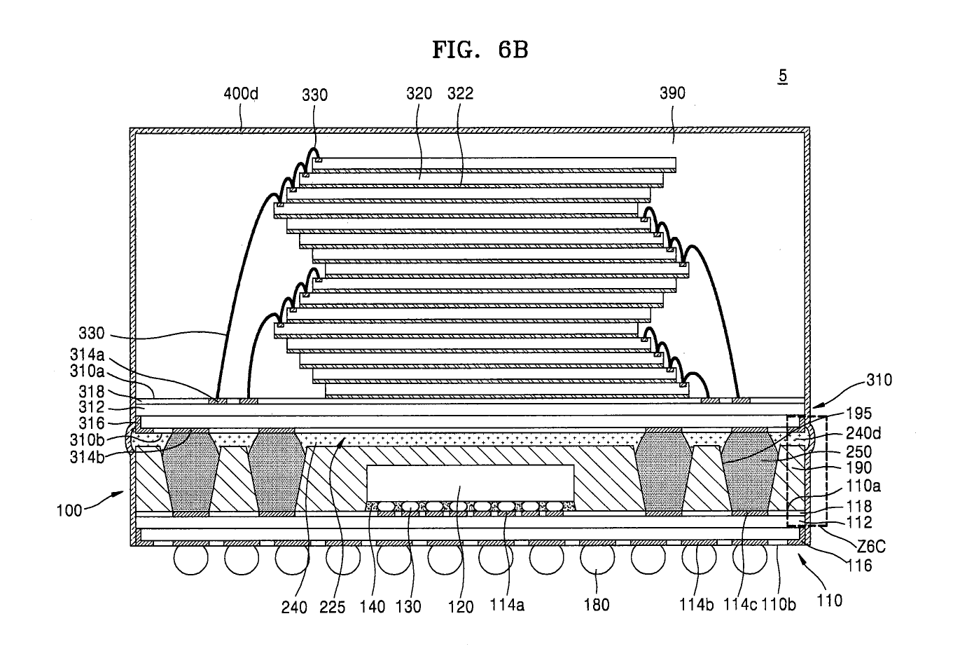

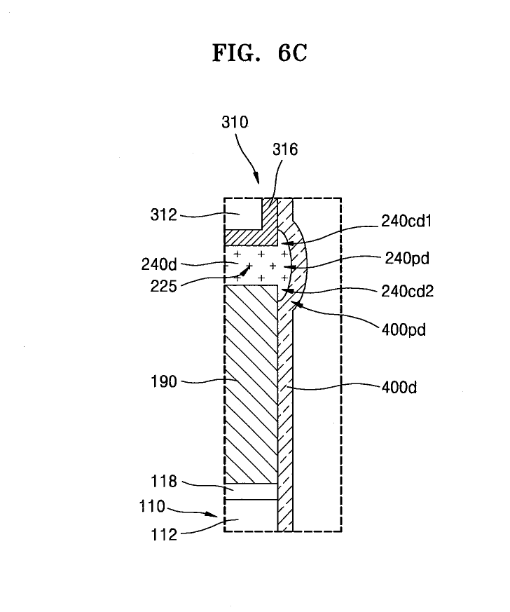

FIG. 6A is a cross-sectional view for describing a method of manufacturing a semiconductor package, according to some embodiments. For example, FIG. 6A is a cross-sectional view for describing an operation performed after the operation of FIG. 2D, and details of FIG. 6A overlapping those of FIGS. 2A through 2E may not be provided.

Referring to FIGS. 2D and 6A together, heat and pressure are applied to the lower and upper sub-semiconductor packages 100 and 300 to melt the lower and upper connection vias 150 and 350. Then, the connection via 250 may be formed as the lower and upper connection vias 150 and 350 are combined via a cooling process.

While the connection via 250 is formed, a part of the adhesive layer 200 may also be melted and may flow into the mold via hole 195. Then, a filling layer 240d may be formed from the adhesive layer 200 after a cooling process.

FIGS. 6B and 6C are respectively a cross-sectional view and a partially enlarged cross-sectional view of a semiconductor package 5 according to some embodiments. For example, FIG. 6C is an enlarged cross-sectional view of a region Z6C of FIG. 6B.

When a relatively large pressure is applied to the lower and upper sub-semiconductor packages 100 and 300, a part of the filling layer 240d may become a protruding part 240pd of FIG. 6C that protrudes farther than the side surfaces of the lower and upper sub-semiconductor packages 100 and 300. The protruding part 240pd may further have an upper covering part 240cd1 of FIG. 6C covering the partial lower portion of the side surface of the upper sub-semiconductor package 300 and a lower covering part 240cd2 of FIG. 6C covering the partial upper portion of the side surface of the lower sub-semiconductor package 100. In other words, the side surface of the filling layer 240d may protrude farther than the side surfaces of the lower and upper sub-semiconductor packages 100 and 300 in the same direction. A part of the filling layer 240d may cover the side surfaces of the upper and lower sub-semiconductor packages 300 and 100, such as for example, the partial lower portion of the side surface of the upper package base substrate 310 and/or the partial upper portion of the side surface of the lower mold layer 190, and/or may not cover at least a part of the upper ground terminal 316 exposed at the side surface of the upper package base substrate 310.

Referring to FIGS. 6B and 6C together, an electromagnetic wave shielding member 400d covering the side surface of the lower package base substrate 110, the side surface of the lower mold layer 190, the side surface of the filling layer 240d, the side surface of the upper package base substrate 310, and/or the side and top surfaces of the upper mold layer 390 is formed.

Since the filling layer 240d fills the space between the lower and upper sub-semiconductor packages 100 and 300, a metal material forming the electromagnetic wave shielding member 400d may be prevented from penetrating the space between the lower and upper sub-semiconductor packages 100 and 300 while the electromagnetic wave shielding member 400d is formed.

Since the filling layer 240d has the protruding part 240pd protruding farther than the side surfaces of the lower and upper sub-semiconductor packages 100 and 300 in the same direction, while the electromagnetic wave shielding member 400d is formed, the metal material forming the electromagnetic wave shielding member 400d may be prevented from penetrating an interface between the upper sub-semiconductor package 300 and the filling layer 240d.

Since the filling layer 240d further has the upper covering part 240cd1 covering the partial lower portion of the side surface of the upper sub-semiconductor package 300 and the lower covering part 240cd2 covering the partial upper portion of the side surface of the lower sub-semiconductor package 100, while the electromagnetic wave shielding member 400d is formed, the metal material forming the electromagnetic wave shielding member 400d may be prevented from penetrating an interface between the upper sub-semiconductor package 300 and the filling layer 240d and an interface between the lower sub-semiconductor package 100 and the filling layer 240d.

Accordingly, the adjacent connection vias 250 may be prevented from being shorted by the metal material forming the electromagnetic wave shielding member 400d.

The electromagnetic wave shielding member 400d may have a shielding protruding part 400pd covering the surfaces of the protruding part 240pd, the upper covering part 240cd1, and the lower covering part 240cd2. According to some embodiments, the shielding protruding part 400pd may have an arc shape on a cross-section of the semiconductor package 5 in a vertical direction.

According to some embodiments, a semiconductor package according to an embodiment may not include an electromagnetic wave shielding member like those in FIGS. 2E, 3A, 4A, 5A, and 6A. Since the semiconductor package includes the filling layer 240, 240a, 240b, 240c, or 240d filling between the lower and upper sub-semiconductor package 100 and 300, binding power between the lower and upper sub-semiconductor packages 100 and 300 may be increased. Also, since moisture, metals, impurities, and/or process byproducts are prevented from penetrating into the space between the lower and upper sub-semiconductor packages 100 and 300 by the filling layer 240, 240a, 240b, 240c, or 240d, damage to the connection via 250 may be prevented. Accordingly, reliability of electric connection between the lower and upper sub-semiconductor packages 100 and 300 may be increased.

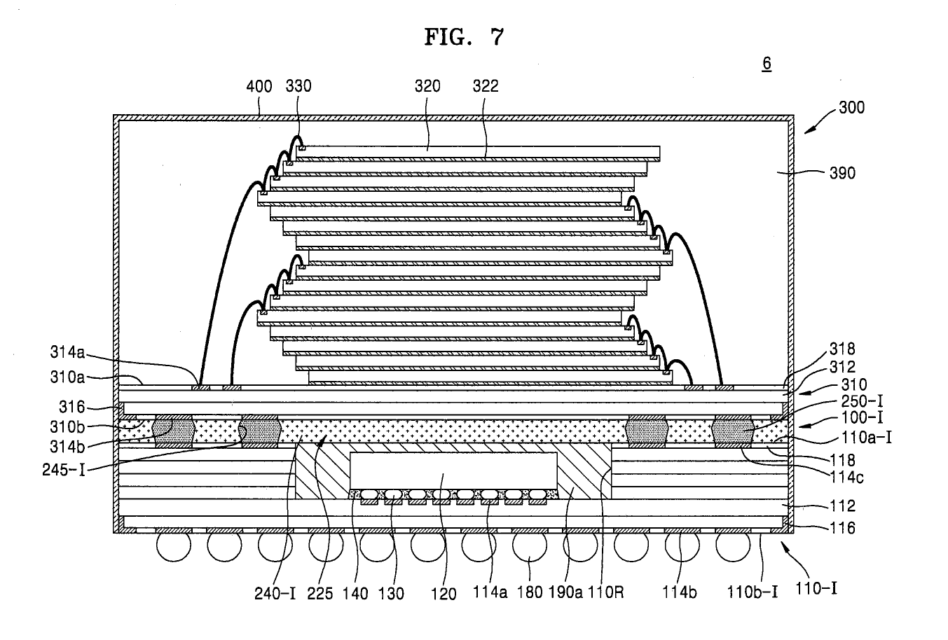

FIGS. 7 through 11 are cross-sectional views of semiconductor packages 6 through 10 according to other embodiments. Details of FIGS. 7 through 11 overlapping those of FIGS. 1A through 6C may not be provided.

Referring to FIG. 7, the semiconductor package 6 includes a lower sub-semiconductor package 100-I, the upper sub-semiconductor package 300 provided over the lower sub-semiconductor package 100-I, and the electromagnetic wave shielding member 400 covering at least some of surfaces of the lower and upper sub-semiconductor packages 100-I and 300. According to some embodiments, the semiconductor package 6 may have a panel level package (PLP) structure.

The lower sub-semiconductor package 100-I may include a lower package base substrate 110-I and the lower semiconductor chip 120 provided on the lower package base substrate 110-I. The lower package base substrate 110-I may have a recessed space 11OR where the lower semiconductor chip 120 is provided. The lower package base substrate 110-I may include at least one lower base layer 112, and/or the first through third lower connection pads 114a through 114c provided on a top surface 110a-I and a bottom surface 110b-I of the lower package base substrate 110. The lower solder resist layer 118 may be provided on the top and bottom surfaces of the lower base layer 112. According to some embodiments, the lower solder resist layer 118 may be provided only on the bottom surface of the lower base layer 112, and may not be provided on the top surface.

A lower mold layer 190a may surround the lower semiconductor chip 120 and fill the recessed space 110R. The lower mold layer 190a may not cover the top surface 110a-I of the lower package base substrate 110-I, and may fill the recessed space 110R.

A filling layer 240-I filling a space between the lower sub-semiconductor package 100-I and the upper sub-semiconductor package 300 may be provided between the lower sub-semiconductor package 100-I and the upper sub-semiconductor package 300. The filling layer 240-I may include the insulating filler 225. The filling layer 240-I may cover the lower mold layer 190a and the top surface 110a-I of the lower package base substrate 110-I, and surround a side surface of a connection via 250-I. According to some embodiments, the filling layer 240-I may directly contact the top surface of the lower mold layer 190a, the top surface 110a-I of the lower package base substrate 110-I, and the bottom surface 310b of the upper package base substrate 310 so as to completely fill the space between the lower and upper sub-semiconductor packages 100-I and 300.

The filling layer 240-I may have a through via hole 245-I. The through via hole 245-I may have a shape in which a lower portion and/or an upper portion are narrow and/or an intervening portion is wide.

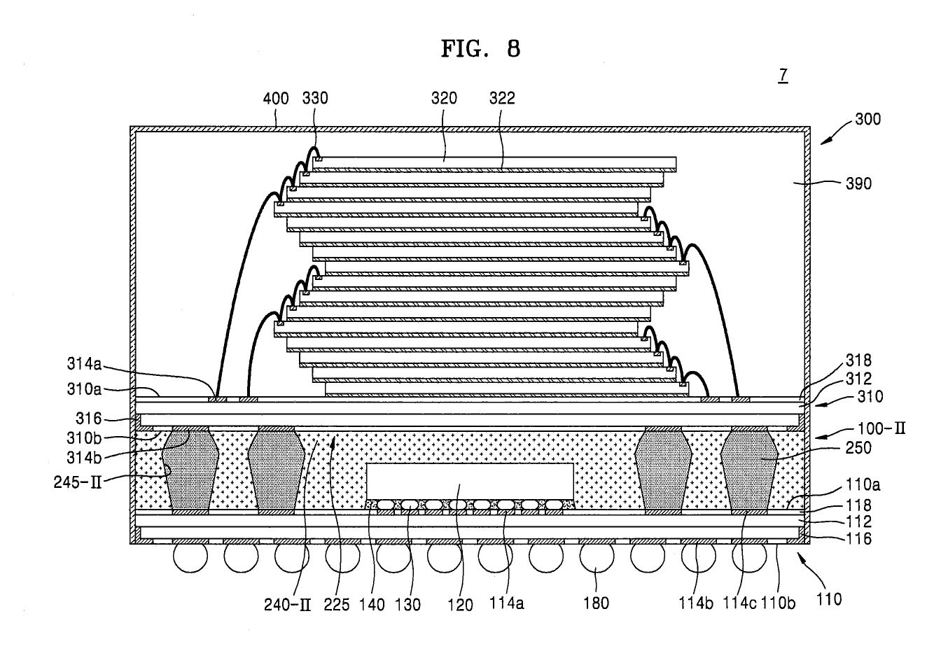

FIG. 8 is a cross-sectional view of the semiconductor package 7 according to some embodiments.

Referring to FIG. 8, the semiconductor package 7 includes a lower sub-semiconductor package 100-II, the upper sub-semiconductor package 300 provided over the lower sub-semiconductor package 100-II, and the electromagnetic wave shielding member 400 covering at least some of surfaces of the lower and/or upper sub-semiconductor packages 100-II and 300.

A filling layer 240-II filling a space between the lower and upper sub-semiconductor packages 100-II and 300 may be provided between the lower and upper sub-semiconductor packages 100-II and 300. The filling layer 240-II may include the insulating filler 225. The filling layer 240-II may cover a top surface 110a-II of a lower package base substrate 110-II, and/or surround the side surface of the connection via 250 and/or the side and top surfaces of the lower semiconductor chip 120. According to some embodiments, the filling layer 240-II may directly contact the top surface 110a-II of the lower package base substrate 110-II and/or the bottom surface 310b of the upper package base substrate 310 to completely fill the space between the lower and upper sub-semiconductor packages 100-II and 300.

The filling layer 240-II may have a through via hole 245-II. The through via hole 245-II may have a shape in which lower and/or upper portions are narrow and/or an intervening portion is wide.

A shape of the filling layer 240-II is similar to a shape in which the lower mold layer 190 and the filling layer 240 of FIG. 1 A are combined, and thus details thereof are not provided. In other words, the lower sub-semiconductor package 100-I included in the semiconductor package 7 does not include the lower mold layer 190 of FIG. 1A, and/or the filling layer 240-II of the semiconductor package 7 may correspond to the lower mold layer 190 and the filling layer 240 of FIG. 1A.

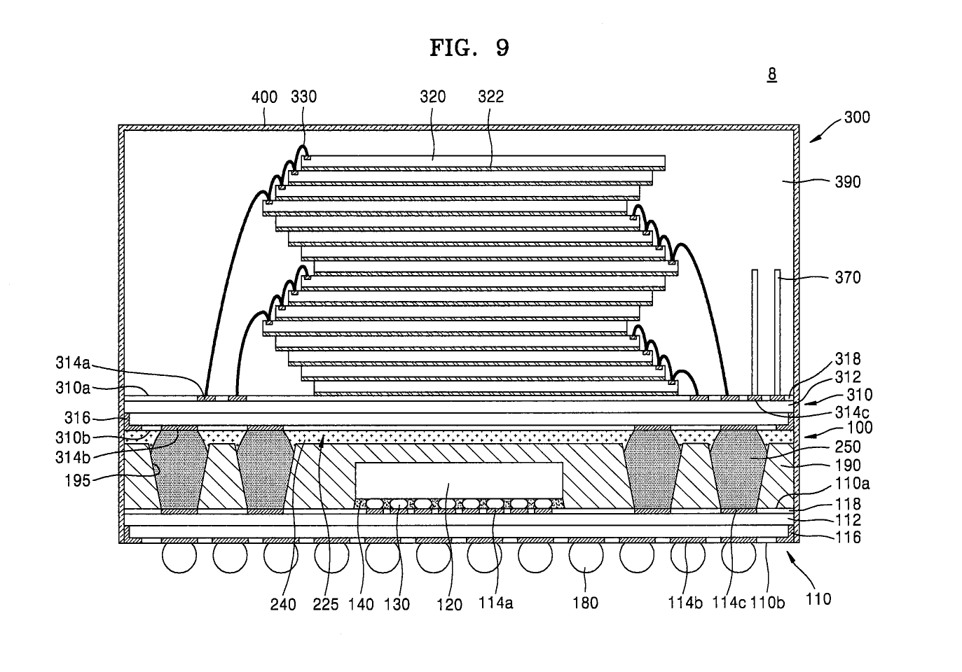

FIG. 9 is a cross-sectional view of the semiconductor package 8 according to an embodiment.

Referring to FIG. 9, the semiconductor package 8 includes the lower sub-semiconductor package 100, the upper sub-semiconductor package 300 provided over the lower sub-semiconductor package 100, and/or the electromagnetic wave shielding member 400 covering at least some of the surfaces of the lower and upper sub-semiconductor packages 100 and 300.

The upper sub-semiconductor package 300 further includes an upper passive device 370. The upper passive device 370 may be, for example, a resistor, a capacitor, an inductor, a filter, a DC-DC converter, a clock-generating quartz, or a temperature sensor. The upper passive device 370 may be electrically connected to a third upper connection pad 314c provided on the top surface 310a of the upper package base substrate 310. The upper passive device 370 may be surrounded by the upper mold layer 390.

The semiconductor package 8 has a structure similar to that of the semiconductor package 1 of FIGS. 1 A and 1B except that the semiconductor package 8 further includes the upper passive device 370 and the third upper connection pad 314c, and thus details thereof are not provided.

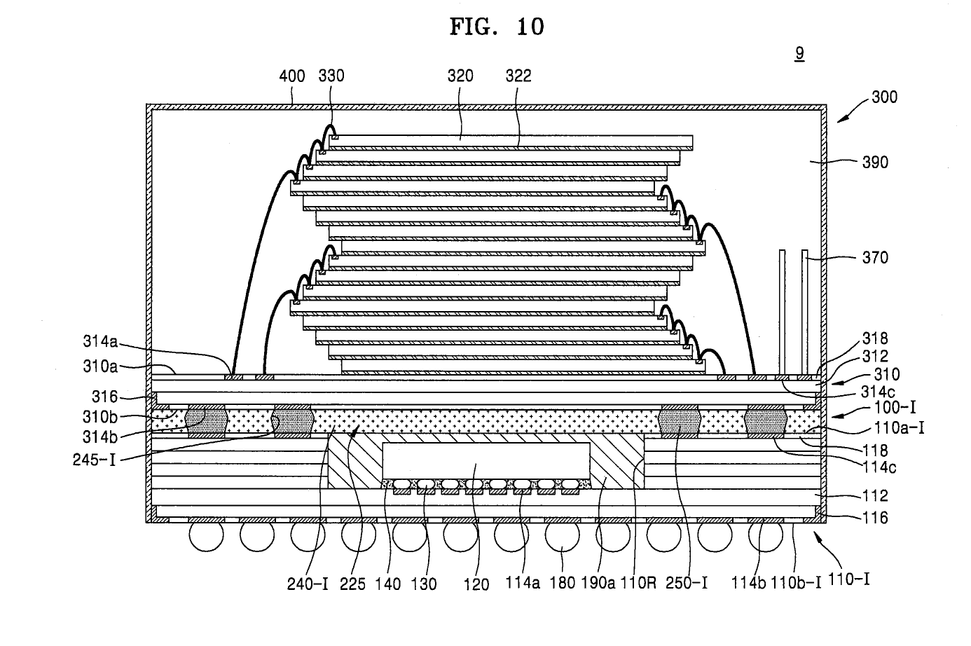

FIG. 10 is a cross-sectional view of the semiconductor package 9 according to some embodiments.

Referring to FIG. 10, the semiconductor package 9 includes the lower sub-semiconductor package 100-I, the upper sub-semiconductor package 300 provided over the lower sub-semiconductor package 100-I, and the electromagnetic wave shielding member 400 covering at least some of the surfaces of the lower and upper sub-semiconductor packages 100-I and 300.

The upper sub-semiconductor package 300 further includes the upper passive device 370. The upper passive device 370 may be electrically connected to the third upper connection pad 314c provided on the top surface 310a of the upper package base substrate 310. The upper passive device 370 may be surrounded by the upper mold layer 390.

The semiconductor package 9 has a structure similar to that of the semiconductor package 6 of FIG. 7 except that the semiconductor package 9 further includes the upper passive device 370 and the third upper connection pad 314c, and thus details thereof are not provided.

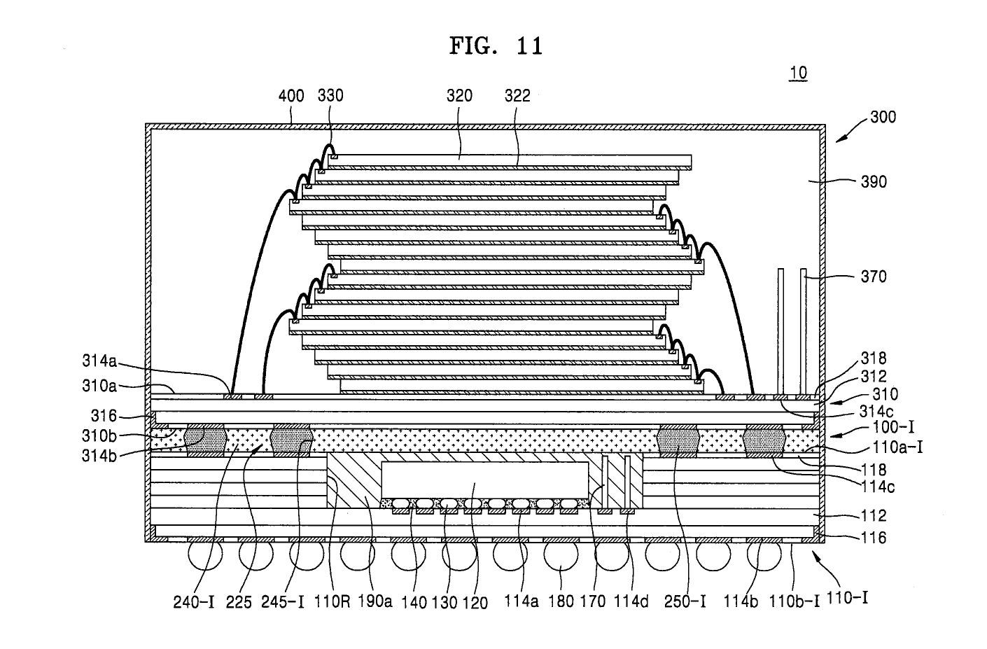

FIG. 11 is a cross-sectional view of the semiconductor package 10 according to an embodiment.

Referring to FIG. 11, the semiconductor package 10 includes the lower sub-semiconductor package 100-I, the upper sub-semiconductor package 300 provided over the lower sub-semiconductor package 100-I, and/or the electromagnetic wave shielding member 400 covering at least some of the surfaces of the lower and upper sub-semiconductor packages 100-I and 300.

The lower sub-semiconductor package 100-I further includes a lower passive device 170. The lower passive device 170 may be, for example, a resistor, a capacitor, an inductor, a filter, a DC-DC converter, a clock-generating quartz, or a temperature sensor. The lower passive device 170 may be electrically connected to a fourth lower connection pad 114d provided at a bottom surface of the recessed space 11OR of the lower package base substrate 110-I. The lower passive device 170 may be surrounded by the lower mold layer 190a.

The upper sub-semiconductor package 300 may include the upper passive device 370. The upper passive device 370 may be electrically connected to the third upper connection pad 314c provided on the top surface 310a of the upper package base substrate 310. The upper passive device 370 may be surrounded by the upper mold layer 390.

The semiconductor package 10 has a structure similar to that of the semiconductor package 9 of FIG. 10 except that the semiconductor package 10 further includes the lower passive device 170 and the fourth lower connection pad 114d, and thus details thereof are not provided.

Although not separately illustrated, it would be obvious to one of ordinary skill in the art that side surface shapes of the filling layers 240, 240-I, and/or 240-II of the semiconductor packages 6 through 10 and/or shapes of the electromagnetic wave shielding member 400 of FIGS. 7 through 11 may be changed similarly to those of the filling layers 240a through 240d of the semiconductor packages 2 through 5 and those of the electromagnetic wave shielding members 400a through 400d of FIGS. 3A through 6C.

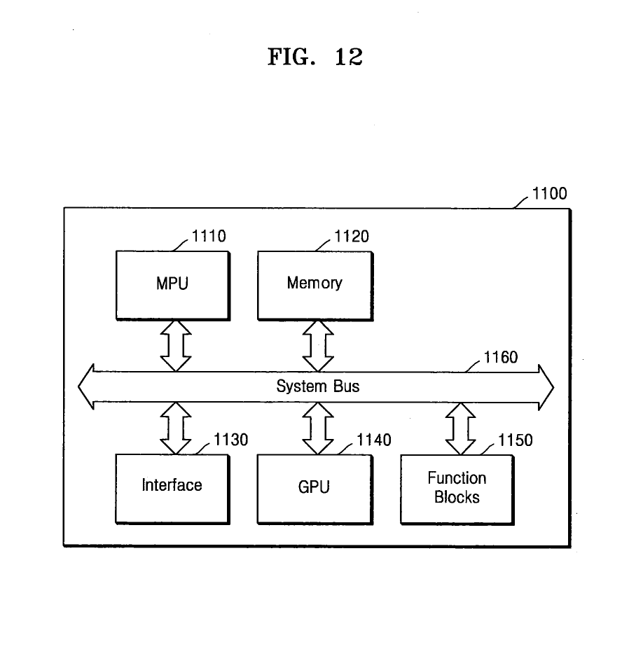

FIG. 12 is a diagram of a configuration of a semiconductor package 1100, according to some embodiments.

Referring to FIG. 12, the semiconductor package 1100 may include a micro-processing unit (MPU) 1110, a memory 1120, an interface 1130, a graphic processing unit (GPU) 1140, function blocks 1150, and/or a system bus 1160 connecting them. The semiconductor package 1100 may include both or one of the MPU 1110 and the GPU 1140.

The MPU 1110 may include a core and an L2 cache. For example, the MPU 1110 may include a multi-core. Each core of the multi-core may have same or different performances. Also, each core of the multi-core may be activated simultaneously or at different times. The memory 1120 may store process results of the function blocks 1150 according to control of the MPU 1110. For example, the MPU 1110 may store information stored in the L2 cache in the memory 1120 as the information is flushed. The interface 1130 may interface with external apparatuses. For example, the interface 1130 may interface with a camera, a liquid crystal display (LCD), and/or a speaker.

The GPU 1140 may perform graphic functions. For example, the GPU 1140 may perform video codec operations or process 3-dimensional (3D) graphics.

The function blocks 1150 may perform various functions. For example, when the semiconductor package 1100 is an application processor (AP) used in a mobile device, some of the function blocks 1150 may perform a communication function.

The semiconductor package 1100 may be one of the semiconductor packages 1 through 10 described with reference to FIGS. 1A through 11. The MPU 1110 and/or the GPU 1140 may be one of the lower sub-semiconductor packages 100, 100-I, and 100-II described with reference to FIGS. 1A through 11. The memory 1120 may be the upper sub-semiconductor package 300 described with reference to FIGS. 1A through 11. The interface 1130 and the function blocks 1150 may correspond to a part of one of the lower sub-semiconductor packages 100, 100-I, and 100-II described with reference to FIGS. 1A through 11.

Since electric reliability of the semiconductor package 1100 is high, the semiconductor package 1100 may have high reliability.

As used herein, the term “and/or” includes any and all combinations of one or more of the associated listed items. Expressions such as “at least one of,” when preceding a list of elements, modify the entire list of elements and do not modify the individual elements of the list.

While the inventive concept has been particularly shown and described with reference to embodiments thereof, it will be understood that various changes in form and details may be made therein without departing from the spirit and scope of the following claims.

1. A semiconductor package comprising:
a lower sub-semiconductor package comprising a lower semiconductor chip, a lower mold layer on the lower semiconductor chip, and a mold via hole;
an upper sub-semiconductor package comprising an upper semiconductor chip;
a filling layer that is between the lower sub-semiconductor package and the upper sub-semiconductor package; and
a connection via in the mold via hole that penetrates the lower mold layer and the filling layer, and electrically connects the lower sub-semiconductor package to the upper sub-semiconductor package,
wherein the filling layer comprises an extending part that extends into the mold via hole from a portion of the filling layer having a higher level than a top surface of the lower mold layer.

2. The semiconductor package of claim 1, further comprising:
an electromagnetic wave shielding member on a side surface of the lower sub-semiconductor package, a side surface of the filling layer, and/or side and/or top surfaces of the upper sub-semiconductor package.

3. The semiconductor package of claim 2, wherein the filling layer comprises a protruding part that protrudes farther than the side surface of the lower sub-semiconductor package and/or the side surface of the upper sub-semiconductor package in a same direction.

4. The semiconductor package of claim 3, wherein the electromagnetic wave shielding member comprises a shielding protruding part that is on a surface of the Page 3 protruding part of the filling layer.

5. The semiconductor package of claim 2, wherein the filling layer further comprises a lower covering part that is on an upper portion of the side surface of the lower sub-semiconductor package.

6. The semiconductor package of claim 2, wherein the filling layer further comprises an upper covering part that is on a lower portion of the side surface of the upper sub-semiconductor package.

7. The semiconductor package of claim 2, wherein the electromagnetic wave shielding member comprises a metal material.

8. The semiconductor package of claim 1, wherein the mold via hole extends from the top surface of the lower mold layer to a bottom surface of the lower mold layer, and
wherein the mold via hole comprises a tapered width shape.

9. The semiconductor package of claim 1, wherein the connection via comprises a widest width at a level lower than the top surface of the lower mold layer.

10. The semiconductor package of claim 1, wherein the connection via comprises a widest width at a portion that contacts a lowermost end of the extending part of the filling layer.

11. A semiconductor package comprising:
a lower sub-semiconductor package comprising a lower package base substrate, a lower semiconductor chip on the lower package base substrate, and a lower mold layer on the lower semiconductor chip on a top surface of the lower package base substrate, wherein the lower mold layer comprises a mold via hole;
an upper sub-semiconductor package comprising an upper package base substrate and an upper semiconductor chip on the upper package base substrate;
a filling layer that is between the lower sub-semiconductor package and the upper sub-semiconductor package;
a connection via in the mold via hole that penetrates the lower mold layer and the filling layer, and electrically connects the lower package base substrate to the upper package base substrate; and
an electromagnetic wave shielding member that is on a side surface of the lower sub-semiconductor package, a side surface of the filling layer, and/or side and/or top surfaces of the upper sub-semiconductor package,
wherein the connection via comprises a widest width at a level lower than a top surface of the lower mold layer.

12. The semiconductor package of claim 11, wherein at least one of the lower package base substrate or the upper package base substrate comprises a ground terminal that is exposed at a side thereof, and
wherein the electromagnetic wave shielding member contacts the ground terminal and is electrically connected to the ground terminal.

13. The semiconductor package of claim 12, wherein the filling layer comprises a protruding part that protrudes farther than the side surface of the lower sub-semiconductor package and/or the side surface of the upper sub-semiconductor package in a direction, and
wherein the filling layer comprises a covering part that is on at least one of a part of the side surface of the lower sub-semiconductor package or a part of the side surface of the upper sub-semiconductor package.

14. The semiconductor package of claim 13, wherein the covering part does not cover at least a part of the ground terminal.

15. The semiconductor package of claim 11, wherein the filling layer comprises an extending part that extends into the mold via hole from a portion of the filling layer having a higher level than the top surface of the lower mold layer, and
wherein the connection via comprises a widest width at a portion contacting a lowermost end of the extending part.

16-20. (canceled)

21. A semiconductor package comprising:
a first semiconductor package comprising a first semiconductor chip;
an encapsulating layer on the first semiconductor chip;
a insulating layer that is on the encapsulating layer; and
a first connection via in a first via hole in the encapsulating layer and a second connection via in a second via hole in the encapsulating layer, wherein the first connection via and the second connection via extend through the encapsulating layer and the insulating layer,
wherein a portion of the insulating layer extends into the first via hole and/or the second via hole, and
wherein the insulating layer extends between the first connection via and the second connection via such that the insulating layer electrically isolates the first connection via from the second connection via.

22. The semiconductor package of claim 21, further comprising:
an electromagnetic wave shielding member on a side surface of the insulating layer, and/or a side surface of the encapsulating layer,
wherein the insulating layer extends between the electromagnetic wave shielding member and the first connection via or the second connection via such that the insulating layer electrically isolates the electromagnetic wave shielding member from the first connection via and/or the second connection via.

23. The semiconductor package of claim 21, wherein the extending part of the insulating layer extends along a sidewall of the first connection via and/or along a sidewall of the second connection via from a portion of the insulating layer having a higher level than a top surface of the encapsulating layer.

24. The semiconductor package of claim 21, further comprising:
a second semiconductor package comprising a second semiconductor chip; and
a ground terminal,
wherein the first connection via and/or the second connection via are spaced apart from the first semiconductor chip and electrically connect the first semiconductor package to the second semiconductor package, and
wherein the insulating layer extends between the ground terminal and the first connection via and/or the second connection via such that the insulating layer electrically isolates the ground terminal from the first connection via and/or the second connection via.

25. The semiconductor package of claim 21, wherein the extending part of the insulating layer decreases in width as the extending part of the insulating layer extends from a top surface of the encapsulating layer along a sidewall of the first connection via and/or along a sidewall of the second connection via.
